(19) United States
(12) Patent Application Publication
(10) Pub. No.: US 2026/0288108 A1
(43) Pub. Date: Sep. 24, 2026

(54) APPARATUS AND METHOD FOR MANUFACTURING SEMICONDUCTOR DEVICE AND APPARATUS AND METHOD FOR SETTING PROCESSING CONDITIONS USED IN MANUFACTURING THE SAME

(71) Applicant: Kioxia Corporation, Tokyo (JP)

(72) Inventor: Yuta MANABE, Yokkaichi Mie (JP)

(21) Appl. No.: 19/318,298

(22) Filed: Sep. 3, 2025

(30) Foreign Application Priority Data
Mar. 24, 2025 (JP) 2025-048084

(51) Int. Cl. G05B 19/18; H01L 21/308; H01L 21/311; H01L 21/3213; H01L 21/67

(52) U.S. Cl. CPC G05B 19/188; H10P 72/0421; G05B 2219/45031; H10P 50/691; H10P 50/71; H10P 50/73

(57) ABSTRACT

A method for manufacturing a semiconductor device employs a condition setting method that includes sequentially shifting a step of interest among multiple steps of substrate processing from a first step to a last step; and at each step of interest, determining a processing condition for optimizing a processed shape during the step of interest, and using the determined processing condition as a beginning processing condition in another step of the multiple steps.

### CROSS-REFERENCE TO RELATED APPLICATION(S)

This application is based upon and claims the benefit of priority from Japanese Patent Application No. 2025-048084, filed Mar. 24, 2025, the entire contents of which are incorporated herein by reference.

### FIELD

Embodiments described herein relate generally to an apparatus and method for manufacturing a semiconductor device, and apparatus and method for setting processing conditions used in manufacturing the same.

### BACKGROUND

In substrate processing such as dry etching, a substrate is processed. It is desirable that processing conditions be efficiently set before this substrate processing.

### BRIEF DESCRIPTION OF THE DRAWINGS

FIG. 1 is a flowchart illustrating a method for manufacturing a semiconductor device to which a condition setting method according to an embodiment is applied.

FIG. 2 is a diagram illustrating candidate processing conditions that does not satisfy a predetermined condition in the embodiment.

FIG. 3 is a block diagram illustrating a functional component of a condition setting device to which the condition setting method according to the embodiment is applied.

FIG. 4 is a block diagram illustrating a hardware configuration of the condition setting device to which the condition setting method according to the embodiment is applied.

FIG. 5 is a diagram illustrating a configuration of a substrate processing apparatus in the embodiment.

FIG. 6 is a diagram illustrating each of multiple steps in the embodiment.

FIG. 7 is a diagram illustrating a procedure of optimizing a processing condition for each of the multiple steps in the embodiment.

FIG. 8 is a diagram illustrating a procedure of optimizing a processing condition for each of multiple steps in a first modification example of the embodiment.

FIG. 9 is a flowchart illustrating condition setting processing in a second modification example of the embodiment.

FIG. 10 is a flowchart illustrating condition search processing in the second modification example of the embodiment.

FIG. 11 is a flowchart illustrating the condition search processing in the second modification example of the embodiment.

FIGS. 12-14 are diagrams illustrating parameters associated with the shape of a processed substrate in a third modification example of the embodiment.

FIGS. 15-20 are diagrams illustrating use cases for optimizing processing conditions in a fourth modification example of the embodiment.

### DETAILED DESCRIPTION

Embodiments provide a condition setting method, a method for manufacturing a semiconductor device, and a condition setting device, all of which enables efficient setting of conditions for substrate processing.

In general, according to one embodiment, there is provided a condition setting method. The condition setting method includes sequentially shifting a step of interest among multiple steps of substrate processing from a first step to a last step; and at each step of interest, determining a processing condition for optimizing a processed shape during the step of interest, and using the determined processing condition as a beginning processing condition in another step of the multiple steps.

A condition setting method according to an embodiment will be described in detail below with reference to the appended drawings. It is noted that the present invention is not limited to this embodiment.

### Embodiment

The condition setting method according to the embodiment is used to efficiently set processing conditions for substrate processing.

To manufacture a semiconductor device, a predetermined film is deposited on a substrate, the predetermined film is coated with a photosensitive material, a predetermined latent image pattern is formed on the photosensitive material by exposure, the predetermined latent image pattern is developed, etching is conducted by using the pattern on the photosensitive material as a mask, and the pattern on the photosensitive material is transferred to the predetermined film. The predetermined film is treated in this manner.

Manufacturing a semiconductor device includes substrate processing such as coating, exposure, development, etching, cleaning, impurity doping, film formation, and heat treatment. The etching includes dry etching and wet etching.

The substrate processing sometimes undergoes a dynamic change in the processing environment during processing. To accommodate the dynamic change in the processing environment during the processing, it is conceivable to divide the whole of the process of the processing by the substrate processing into multiple steps and optimize processing conditions for each of the multiple steps. However, since the processing conditions in each step may influence the processing in subsequent steps, it can be difficult to optimize the processing conditions for all steps simultaneously. Furthermore, the number of combinations of process parameters across the multiple steps become enormous, making it difficult to efficiently search for solutions.

For example, in dry etching, which is one type of substrate processing, a shape having a high aspect ratio is sometimes desired. During dry etching, the treatment environment may change dynamically. The change in the aspect ratio during the treatment may be followed by a change in the ratio between ions and radicals reaching the treated surface and the like. Accordingly, the optimal processing conditions are expected to change dynamically.

To accommodate this dynamic change in the treatment environment during the treatment, it is conceivable to divide the treatment by dry etching into multiple steps depending on the gradual steps of the progress of the treatment and optimize processing conditions for each of the multiple steps. The optimization of the processing conditions means changing the processing condition in a direction (e.g., improving direction) in which the processing condition does not deteriorate or in a direction in which it is possible to consider that the processing condition does not deteriorate (e.g., in a direction in which it is possible to keep the processing condition within a permissible range regardless of the improving direction or a deteriorating direction). In addition, the processing conditions of one step may influence the processing in subsequent steps. This makes it difficult to optimize the processing conditions for all the steps simultaneously. For example, in a case in which the processed shape obtained in a certain step of the multiple steps deviates from the desired shape, additional processing will be performed on that deviated shape. As a result, the processed shape may deviate even further from the desired shape, making correction or improvement difficult.

Accordingly, in the embodiment, in the condition setting method, the optimization of assigning a processing condition in a step of interest to be optimized among the multiple steps and using the processing condition as a temporary processing condition in another step to improve a processed shape while sequentially shifting the step of interest from the first step to the last step is repeated, thereby efficiently setting a processing condition.

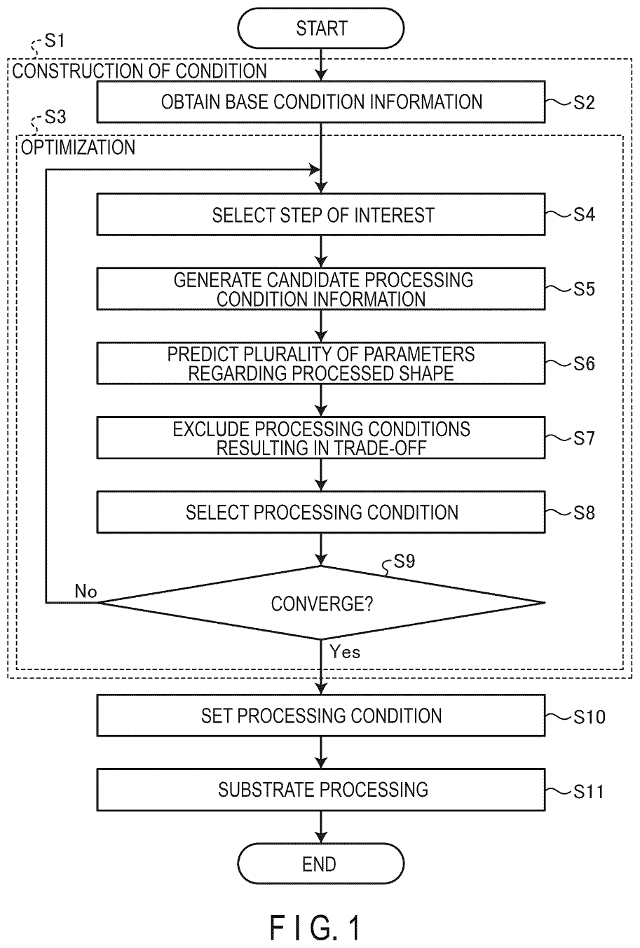

The method for manufacturing the semiconductor device to which the condition setting method is applied may be carried out as illustrated in FIG. 1. FIG. 1 is a flowchart illustrating the method for manufacturing the semiconductor device to which the condition setting method is applied.

For the substrate processing having multiple steps, processing conditions for the respective multiple steps are set (S1). Within S1, S2 and S3 are performed.

In S1, a base condition for each of the multiple steps is obtained (S2). The base condition is a default processing condition. The base condition may be experimentally determined in advance, for example, by causing the substrate processing apparatus to process a prototype substrate.

For example, in a case in which the substrate processing is dry etching, the base condition includes a condition relating to default power supply electricity, a default power supply frequency, a default power supply pulse period, default power supply pulse width, a default process gas flow rate, a default process gas in-plane supply rate, a default auxiliary gas flow rate, default treatment chamber pressure, default treatment time, default heating temperature, default chiller temperature, or the like.

The condition relating to the default power supply electricity includes the default magnitude of electricity for accelerating ions in a treatment chamber.

The condition relating to the default power supply frequency includes the default frequency height for accelerating ions in a treatment chamber.

The condition relating to the default power supply pulse period includes the default length of a pulse period for accelerating ions in a treatment chamber.

The condition relating to the default power supply pulse width includes the default length of pulse width for accelerating ions in a treatment chamber.

The condition relating to the default process gas flow rate includes the default rate of process gas flowing per unit time from a tank of process gas to a treatment chamber.

The condition relating to the default process gas in-plane supply rate includes the default rate of process gas supplied per unit time from a tank of process gas to the front surface of a substrate in a treatment chamber.

The condition relating to the default auxiliary gas flow rate includes the default rate of auxiliary gas flowing per unit time from a tank of auxiliary gas (e.g., He gas) to the back surface of a substrate in a treatment chamber.

The condition relating to the default treatment chamber pressure includes the default pressure of process gas to be maintained in a treatment chamber.

The condition relating to the default treatment time includes default time for which treatment is to be conducted in a treatment chamber.

The condition relating to the default heating temperature includes the default heating temperature of a substrate to be maintained by a heating element in a treatment chamber.

The condition relating to the default chiller temperature includes the default cooling temperature of a substrate to be maintained by a chiller element in a treatment chamber.

A processing condition for each of the multiple steps is optimized (S3). The processing conditions may be optimized from a processing condition for the first step to a processing condition for the last step of the multiple steps in order. Within S3, S4 to S9 are performed.

For example, in a case in which the substrate processing is dry etching, a processing condition for each of the steps is a condition relating to the power supply electricity in the step, the process gas flow rate in the step, the treatment chamber pressure in the step, the substrate temperature in the step, or the like.

In S3, a step of interest among the multiple steps is selected (S4). The first step of the non-selected steps among the multiple steps may be selected as a step of interest.

One or more candidate processing conditions are generated for the step of interest (S5). The candidate processing conditions are candidates for processing conditions with each of which a reference processing condition is to be replaced. The reference processing condition is the base condition for the first time through the loop or a processing condition selected in S8 described below for the second time or later through the loop. At this time, a reference processing condition is still applied to steps other than the step of interest.

For example, in a case in which the substrate processing is dry etching and the base condition is the default power supply electricity, one or more candidate power supply electricity are generated for the step of interest (S5). The candidate power supply electricity are candidates for power supply electricity with which the default power supply electricity is to be replaced. For example, power supply electricity more than the default power supply electricity and power supply electricity less than the default power supply electricity are generated as the one or more candidate power supply electricity. The base condition is the default power supply electricity for the first time through the loop and is a condition relating to power supply electricity selected in S8 described below for the second time and later through the loop. At this time, the default power supply electricity is still applied to a step other than the step of interest.

A plurality of parameters relating to a processed shape is predicted under each of the reference processing condition and the one or more candidate processing conditions for the step of interest (S6). The plurality of parameters relating to a processed shape obtained in a case in which any of processing conditions for the respective steps including the step of interest is a reference processing condition is predicted. The plurality of parameters relating to a processed shape obtained in a case in which a processing condition for the step of interest among the multiple steps is a candidate processing condition and the reference processing condition is applied to another step is predicted.

For example, in a case in which the substrate processing is dry etching and the base condition is the default power supply electricity, a plurality of parameters relating to a processed shape is predicted under each of the default power supply electricity and the one or more candidate power supply electricity for the step of interest (S6). That is, the plurality of parameters relating to the processed shape is predicted under each of the default power supply electricity, power supply electricity more than the default power supply electricity, and power supply electricity less than the default power supply electricity. The plurality of parameters relating to a processed shape obtained in a case in which any of power supply electricity for the respective steps including the step of interest is the default power supply electricity is predicted. The plurality of parameters relating to a processed shape obtained in a case in which a power supply electricity for the step of interest among the multiple steps is a candidate power supply electricity and the default power supply electricity is applied to another step is predicted.

The processed shape in the step of interest among the multiple steps may be predicted under each of the reference processing condition and the one or more candidate processing conditions and the plurality of parameters may be extracted from the predicted processed shape. The processed shape may be predicted by using a model subjected to machine learning to output a processed shape depending on a processing condition or by using an expression such as a function that expresses a processed shape corresponding to a processing condition.

Each of the plurality of parameters may be a parameter indicating a feature of a processed cross-sectional shape or a parameter indicating a feature of a processed planar shape.

The plurality of parameters is each used to evaluate the degree of optimization of a processed shape. The permissible range of each of the plurality of parameters may be experimentally determined in advance.

For example, in a case in which the substrate processing is hole patterning by dry etching, the plurality of parameters includes parameters relating to the upper blockage rate of a cross-sectional shape, the degree of bowing of a cross-sectional shape, the degree of twisting of a cross-sectional shape, the degree of bending of a cross-sectional shape, the degree of tilting of a cross-sectional shape, the bottom blockage rate of a cross-sectional shape, the film thickness of a remaining hard mask, the degree of distortion of a planar shape, an etching rate, and the like.

The parameter relating to the upper blockage rate of a cross-sectional shape includes the degree to which the upper side surface is blocked with respect to the reference side surface of a hole pattern.

The parameter relating to the degree of bowing of a cross-sectional shape includes the degree to which the middle side surface expands outward with respect to the reference side surface of the hole pattern.

The parameter relating to the degree of twisting of a cross-sectional shape includes the degree to which the distance between the side surfaces of adjacent hole patterns from the middles to the bottoms varies between the hole patterns and the degree to which the central axis of the side surface of a hole pattern from the middle to the bottom is tilted with respect to the central axis of the reference side surface of the hole pattern.

The parameter relating to the degree of bending of a cross-sectional shape includes the degree to which the central axis of the side surface of a hole pattern from the middle to the bottom is tilted with respect to the central axis of the reference side surface of the hole pattern.

The parameter relating to the degree of tilting of a cross-sectional shape includes the degree to which the central axis of a hole pattern is tilted with respect to the central axis of the reference side surface of the hole pattern.

The parameter relating to the bottom blockage rate of a cross-sectional shape includes the degree to which the bottom side surface is blocked with respect to the reference side surface of a hole pattern.

The parameter relating to the film thickness of a remaining hard mask includes the thickness of a hard mask at the end of dry etching. The hard mask is required to have a thickness of 0 nm or more at the end of dry etching, but has an appropriate value range.

The parameter relating to the degree of distortion of a planar shape includes the degree to which a hole pattern is distorted with respect to a reference planar shape.

A candidate processing condition that does not satisfy a predetermined condition among the one or more candidate processing conditions is excluded depending on the plurality of parameters predicted in S6 (S7). The candidate processing condition that does not satisfy the predetermined condition is, for example, a candidate processing condition under which two or more parameters are traded off relating to a processed shape or a candidate processing condition resulting in a direction in which at least one or more parameters deteriorate relating to a processed shape or a direction in which it is possible to consider that at least one or more parameters deteriorate relating to a processed shape (e.g., a direction in which it is not possible to maintain the at least one or more parameter within the permissible ranges).

For example, in a case in which the substrate processing is dry etching and the base condition is the default power supply electricity, a candidate power supply electricity under which two or more parameters are traded off relating to a processed shape among the one or more candidate power supply electricity is excluded depending on the plurality of parameters predicted in S6 (S7).

In a case in which the plurality of parameters includes a first parameter and a second parameter, a candidate processing condition under which at least one of the first parameter and the second parameter deteriorates more than under the reference processing condition may be excluded as a candidate processing condition that does not satisfy the predetermined condition.

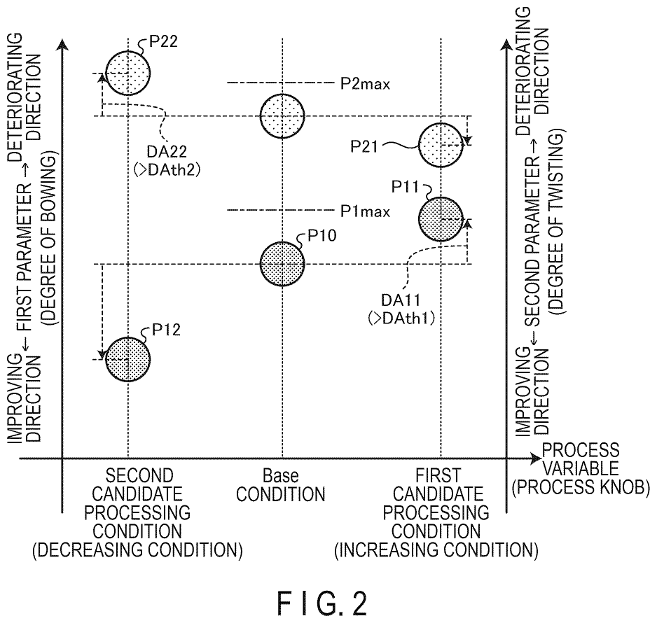

For example, as illustrated in FIG. 2, a case in which one or more candidate processing conditions include a first candidate processing condition and a second candidate processing condition will be considered. FIG. 2 is a diagram illustrating a candidate processing condition that does not satisfy the predetermined condition. In FIG. 2, the first parameter is, for example, the degree of bowing, the second parameter is, for example, the degree of twisting, and a process variable is, for example, power supply electricity. The process variable is a variable for a processing condition and is also referred to as a process knob.

In FIG. 2, the longitudinal axis on the left side indicates the value of the first parameter, the up direction in FIG. 2 is the deteriorating direction of the first parameter, and the down direction in FIG. 2 is the improving direction of the first parameter. The longitudinal axis on the right side indicates the value of the second parameter, the up direction in FIG. 2 is the deteriorating direction of the second parameter, and the down direction in FIG. 2 is the improving direction of the second parameter. The transverse axis indicates the value of the process variable, the right direction in FIG. 2 is the increasing direction, and the left direction in FIG. 2 is the decreasing direction.

Under the base condition, a point P10 is plotted for the first parameter and a point P20 is plotted for the second parameter.

The first candidate processing condition is a condition (increasing condition) having the value of the process variable higher than that of the base condition. For example, a case in which the value of the power supply electricity is higher applies. Under the first candidate processing condition, a point P11 is plotted for the first parameter and a point P21 is plotted for the second parameter. Under the first candidate processing condition, the first parameter deteriorates more than under the reference processing condition. The first candidate processing condition may be thus excluded as a candidate processing condition that does not satisfy the predetermined condition.

The second candidate processing condition is a condition (decreasing condition) having the value of the process variable lower than that of the base condition. For example, a case in which the value of the power supply electricity is lower applies. Under the second candidate processing condition, a point P12 is plotted for the first parameter and a point P22 is plotted for the second parameter. Under the second candidate processing condition, the second parameter deteriorates more than under the reference processing condition. The second candidate processing condition may thus be excluded as a candidate processing condition that does not satisfy the predetermined condition.

Alternatively, in a case in which the plurality of parameters includes a first parameter and a second parameter, a candidate processing condition under which at least one of the first parameter and the second parameter is improved more than under the reference processing condition and the other deteriorates more than under the reference processing condition may be excluded as a candidate processing condition that does not satisfy the predetermined condition.

In the case of FIG. 2, under the first candidate processing condition, the second parameter is improved more than under the reference processing condition and the first parameter deteriorates more than under the reference processing condition. The first candidate processing condition may be thus excluded as a candidate processing condition that does not satisfy the predetermined condition.

Under the second candidate processing condition, the first parameter is improved more than under the reference processing condition and the second parameter deteriorates more than under the reference processing condition. The second candidate processing condition may thus be excluded as a candidate processing condition that does not satisfy the predetermined condition.

Alternatively, in a case in which the plurality of parameters includes a first parameter and a second parameter, a candidate processing condition under which the amount by which at least one of the first parameter and the second parameter deteriorates more than under the reference processing condition exceeds a threshold may be excluded as a candidate processing condition that does not satisfy the predetermined condition.

In the case of FIG. 2, an amount DA11 by which the first parameter deteriorates more than under the reference processing condition exceeds a threshold DAth1 and the first candidate processing condition may thus be excluded as a candidate processing condition that does not satisfy the predetermined condition. The threshold DAth1 may be experimentally determined in advance as a value indicating a tradeoff border for the amount by which the first parameter deteriorates.

An amount DA22 by which the second parameter deteriorates more than under the reference processing condition exceeds a threshold DAth2 and the second candidate processing condition may be thus excluded as a candidate processing condition that does not satisfy the predetermined condition. The threshold DAth2 may be experimentally determined in advance as a value indicating a tradeoff border for the amount by which the second parameter deteriorates.

Alternatively, in a case in which the plurality of parameters includes a first parameter and a second parameter, a candidate processing condition under which at least one of the first parameter and the second parameter falls out of a permissible range and deteriorates more than under the reference processing condition may be excluded as a candidate processing condition that does not satisfy the predetermined condition.

In the case of FIG. 2, the permissible range of the first parameter is illustrated as the range less than or equal to a permissible upper limit P1max. The permissible upper limit P1max may be experimentally determined in advance as an upper limit value permissible to the first parameter.

The permissible range of the second parameter is illustrated as the range less than or equal to a permissible upper limit P2max. The permissible upper limit P2max may be experimentally determined in advance as an upper limit value permissible to the second parameter.

Under the first candidate processing condition, the first parameter deteriorates more within the permissible range than under the reference processing condition. The first candidate processing condition is thus not excluded as a candidate processing condition that does not satisfy the predetermined condition.

Under the second candidate processing condition, the second parameter falls out of the permissible range and deteriorates more than under the reference processing condition. The second candidate processing condition may thus be excluded as a candidate processing condition that does not satisfy the predetermined condition.

One of one or more processing conditions left after the exclusion of the reference processing condition and the one or more candidate processing conditions for the step of interest is selected as a processing condition for the step of interest (S8). A processing condition under which a plurality of parameters is each within the permissible range among one or more processing conditions left after the exclusion of the reference processing condition and the one or more candidate processing conditions may be selected as a processing condition (search solution) for the step of interest.

For example, in a case in which the substrate processing is dry etching and the base condition is the default power supply electricity, one of one or more power supply electricity left after the exclusion of the default power supply electricity and the one or more candidate power supply electricity for the step of interest is selected as a power supply electricity for the step of interest (S8). A power supply electricity under which a plurality of parameters is each within the permissible range among one or more power supply electricity left after the exclusion of the default power supply electricity and the one or more candidate power supply electricity may be selected as a power supply electricity (search solution) for the step of interest.

In S3, a loop of S4 to S9 is repeated by using each of the multiple steps as a step of interest until the plurality of parameters converges in the permissible ranges in each of the multiple steps (No in S9). In a case in which the loop of S4 to S9 is repeated, a step of interest may be selected (S4) in the order from a processing condition for the first step to a processing condition for the last step of the multiple steps. Therefore, for example, a step subsequent to a step of interest chosen in a certain loop among the multiple steps is selected as a step of interest for the next loop (S4). In a case in which at least one of the plurality of parameters falls out of the permissible range, it is determined that the plurality of parameters does not converge in the permissible ranges. In a case in which all the plurality of parameters falls within the permissible ranges, it is determined that the plurality of parameters converges in the permissible ranges. The processing conditions may be hereby optimized from a processing condition for the first step to a processing condition for the last step of the multiple steps in order.

When the plurality of parameters converges in the permissible ranges in each of the multiple steps (Yes in S9), the condition setting processing (S1) is completed. The processing condition for each of the multiple steps optimized in S3 is set in the substrate processing apparatus (S10). A substrate is introduced to the substrate processing apparatus and the substrate processing having multiple steps is performed under the optimized processing condition for each step (S11).

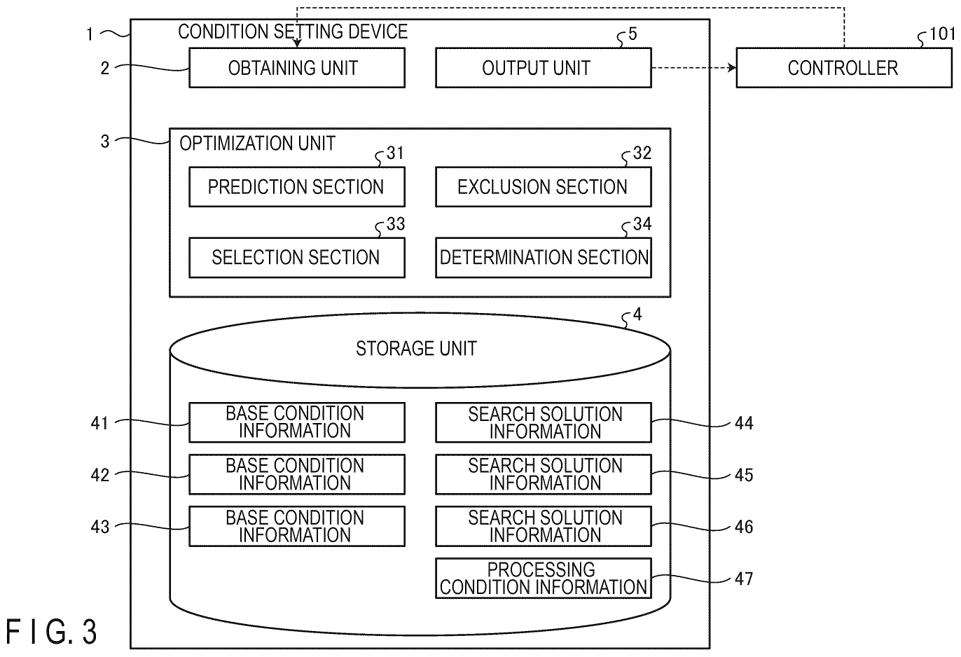

The condition setting processing (S1) illustrated in FIG. 1 may be performed by a condition setting device 1 as illustrated in FIG. 3. FIG. 3 is a block diagram illustrating functional components of the condition setting device 1 to which the condition setting method is applied.

The condition setting device 1 illustrated in FIG. 3 is capable of exchanging information with a controller 101 of a substrate processing apparatus 100. The substrate processing apparatus 100 will be described below.

The condition setting device 1 includes an obtaining unit 2, an optimization unit 3, a storage unit 4, and an output unit 5.

The obtaining unit 2 obtains base condition information for each of the multiple steps from the controller 101. The base condition information is information relating to a base condition that is a default processing condition. The base condition may be experimentally determined in advance, for example, by causing the substrate processing apparatus 100 to process a prototype substrate. The base condition information may be held in the controller 101 in advance. The obtaining unit 2 is relevant to S2 in FIG. 1.

For example, in a case in which the multiple steps include step ST_1 to step ST_3, the obtaining unit 2 may obtain pieces of base condition information 41 to 43 from the controller 101. The pieces of base condition information 41 to 43 are pieces of information indicating the base conditions for step ST_1 to step ST_3, respectively.

The obtaining unit 2 may be configured to allow a recording medium to be connected thereto. In this case, the controller 101 records a base condition in the recording medium and the recording medium is connected to the obtaining unit 2. When the recording medium is connected, the obtaining unit 2 may access the recording medium and obtain the base condition.

Alternatively, the obtaining unit 2 may be configured to be connectable to the controller 101 through a communication medium. The communication medium may be a wired communication line or a wireless communication line. In this case, the obtaining unit 2 may transmit a request to obtain a base condition to the controller 101 through the communication medium, receive the pieces of base condition information 41 to 43 from the controller 101 through the communication medium as a response thereto, and obtain the base conditions.

When obtaining the base condition information for each of the multiple steps, the obtaining unit 2 stores the base condition information for the step in the storage unit 4. The base condition information for each step may be supplied to the optimization unit 3.

For example, in a case in which the multiple steps include step ST_1 to step ST_3, the obtaining unit 2 obtains the pieces of base condition information 41 to 43 for step ST_1 to step ST_3. The obtaining unit 2 may supply the pieces of base condition information 41 to 43 for step ST_1 to step ST_3 to the optimization unit 3 or store the pieces of base condition information 41 to 43 for step ST_1 to step ST_3 in the storage unit 4.

The optimization unit 3 may receive information relating to the reference processing condition for each of the multiple steps from the obtaining unit 2, or may access the storage unit 4 and read information relating to the reference processing condition for each of the multiple steps from the storage unit 4. The optimization unit 3 optimizes a processing condition for each of the multiple steps. The optimization unit 3 may optimize the processing conditions for the respective steps by optimizing a processing condition for the first step to a processing condition for the last step of the multiple steps in order. The optimization unit 3 is relevant to S3 in FIG. 1.

The optimization unit 3 includes a prediction section 31, an exclusion section 32, a selection section 33, and a determination section 34.

The prediction section 31 selects a step of interest among the multiple steps. The prediction section 31 may select the first step of the non-selected steps among the multiple steps. The prediction section 31 is relevant to S4 in FIG. 1.

The prediction section 31 generates one or more candidate processing conditions for the step of interest. The candidate processing conditions are processing conditions with each of which a reference processing condition is to be replaced. The reference processing condition is the base condition in the initial state and a processing condition selected by the selection section 33 after update. The prediction section 31 is relevant to S5 in FIG. 1.

The prediction section 31 predicts a plurality of parameters relating to a processed shape in the step of interest under each of a reference processing condition and one or more candidate processing conditions. The prediction section 31 may predict the processed shape in the step of interest among the multiple steps under each of the reference processing condition and the one or more candidate processing conditions and extract the processed shape in the step of interest from the predicted processed shape. The prediction section 31 may predict a processed shape by using machine learning or predict a processed shape by using an expression. The prediction section 31 is relevant to S6 in FIG. 1.

It is to be noted that the permissible ranges of the plurality of parameters may be experimentally determined and set in the determination section 34 in advance.

The prediction section 31 supplies the plurality of predicted parameters to the exclusion section 32.

The exclusion section 32 excludes a candidate processing condition under which at least one of the parameters deteriorates more than under the reference processing condition among the one or more candidate processing conditions depending on the plurality of predicted parameters. In a case in which the plurality of parameters includes a first parameter and a second parameter, the exclusion section 32 may exclude a candidate processing condition under which one of the first parameter and the second parameter is improved more than under the reference processing condition and the other deteriorates more than under the reference processing condition among the one or more candidate processing conditions as a candidate processing condition under which a processed shape is traded off. The exclusion section 32 is relevant to S7 in FIG. 1.

The selection section 33 selects, as a processing condition for the step of interest, one of one or more processing conditions left after the exclusion of the reference processing condition and the one or more candidate processing conditions. The selection section 33 may select a processing condition under which a plurality of parameters is each within the permissible range among one or more processing conditions left after the exclusion of the reference processing condition and the one or more candidate processing conditions as a processing condition (search solution) for the step of interest. The selection section 33 is relevant to S8 in FIG. 1.

The selection section 33 stores information relating to a selected processing condition for each of the multiple steps in the storage unit 4 as search solution information. The selection section 33 may supply the information relating to the selected processing condition for each of the multiple steps to the determination section 34 as search solution information. The search solution information includes the content of the selected processing condition and the values of a plurality of parameters relevant thereto.

For example, in a case in which the multiple steps include step ST_1 to step ST_3, the selection section 33 may supply pieces of information relating to selected processing conditions for step ST_1 to step ST_3 to the determination section 34 or may store pieces of information relating to step ST_1 to step ST_3 in the storage unit 4 as pieces of search solution information 44 to 46, respectively.

In addition, when the search solutions for the respective steps are obtained, the selection section 33 may generate a processing condition for the multiple steps by merging the search solutions for the respective steps. The selection section 33 may generate processing condition information 47 by merging the pieces of search solution information 44 to 46.

The determination section 34 determines whether or not the plurality of parameters each converges in the permissible range. In a case in which at least one of the plurality of parameters falls out of the permissible range, the determination section 34 determines that the plurality of parameters does not converge in the permissible ranges. In a case in which all the plurality of parameters falls within the permissible ranges, the determination section 34 determines that the plurality of parameters converges in the permissible ranges. Accordingly, the optimization unit 3 completes the construction of a processing condition. The determination section 34 is relevant to S9 in FIG. 1.

This allows the optimization unit 3 to optimize the processing conditions from a processing condition for the first step to a processing condition for the last step of the multiple steps in order. When completing the construction of a processing condition, the optimization unit 3 stores a result thereof in the storage unit 4 as the processing condition information 47.

The output unit 5 outputs the constructed processing condition for the multiple steps to the controller 101. The output unit 5 is relevant to S10 in FIG. 1.

For example, the output unit 5 may read the processing condition information 47 from the storage unit 4 and supply the processing condition information 47 to the controller 101. Each of the pieces of processing condition information 47 is information indicating a processing condition for each of the multiple steps.

The output unit 5 may be configured to allow a recording medium to be connected thereto. In this case, the output unit 5 records a base condition in a recording medium and the recording medium is connected to the controller 101. When the recording medium is connected, the controller 101 may access the recording medium and obtain the processing condition information 47.

Alternatively, the output unit 5 may be configured to be connectable to the controller 101 through a communication medium. The communication medium may be a wired communication line or a wireless communication line. In this case, the output unit 5 may transmit the processing condition information 47 to the controller 101 through a communication medium.

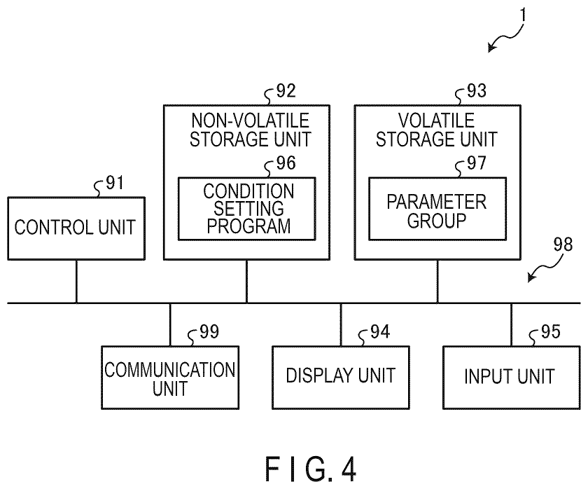

The condition setting device 1 illustrated in FIG. 3 may be implemented as hardware as illustrated in FIG. 4. FIG. 4 is a block diagram illustrating the hardware configuration of the condition setting device to which the condition setting method is applied.

The condition setting device 1 includes a control unit 91, a non-volatile storage unit 92, a volatile storage unit 93, a display unit 94, an input unit 95, and a communication unit 99. The control unit 91, the non-volatile storage unit 92, the volatile storage unit 93, the display unit 94, and the input unit 95 are communicably connected to each other through a bus line 98.

The control unit 91 integrally controls the respective units of the condition setting device 1. The control unit 91 may be implemented as a CPU (Central Processing Unit) or the like.

The non-volatile storage unit 92 stores a condition setting program 96 in a non-volatile manner. The non-volatile storage unit 92 may be implemented as a ROM (Read Only Memory), a flash memory, or the like.

The control unit 91 reads and starts the condition setting program 96 from the non-volatile storage unit 92, and executes the condition setting method in accordance with the condition setting program 96. The condition setting method corresponds to S1 in FIG. 1.

The volatile storage unit 93 temporarily stores information. The volatile storage unit 93 may store a parameter group 97 that is compliant with the condition setting program 96. The parameter group 97 corresponds to the plurality of parameters in the flow of FIG. 1. The volatile storage unit 93 may be implemented as a DRAM (Dynamic Random Access Memory) or the like.

The display unit 94 displays information under the control of the control unit 91. The display unit 94 may be implemented as a display such as a liquid-crystal monitor.

The input unit 95 receives information from the outside and supplies the received information to the control unit 91. The input unit 95 may be implemented as an input interface such as a keyboard, a mouse, or a touch panel. The control unit 91 may perform processing corresponding to the information in accordance with the condition setting program 96.

The communication unit 99 is a communication interface circuit capable of communicating with the outside through a communication line. The communication line may be a wired communication line or a wireless communication line.

The obtaining unit 2 and the output unit 5 illustrated in FIG. 3 may be implemented as the input unit 95 or the communication unit 99. The storage unit 4 illustrated in FIG. 1 may be implemented as the volatile storage unit 93.

Each of the prediction section 31, the exclusion section 32, the selection section 33, and the determination section 34 illustrated in FIG. 3 may be implemented as software. In this case, the prediction section 31, the exclusion section 32, the selection section 33, and the determination section 34 may be all implemented as functional modules that are loaded to the volatile storage unit 93 collectively at the time of compilation or successively depending on the processing progress in response to a start of the condition setting program 96 by the control unit 91.

Alternatively, each of the prediction section 31, the exclusion section 32, the selection section 33, and the determination section 34 illustrated in FIG. 3 may be implemented as hardware. In this case, the prediction section 31, the exclusion section 32, the selection section 33, and the determination section 34 may be each incorporated into the control unit 91 as a circuit.

Alternatively, some of the prediction section 31, the exclusion section 32, the selection section 33, and the determination section 34 illustrated in FIG. 3 may be implemented as software and the other may be implemented as hardware.

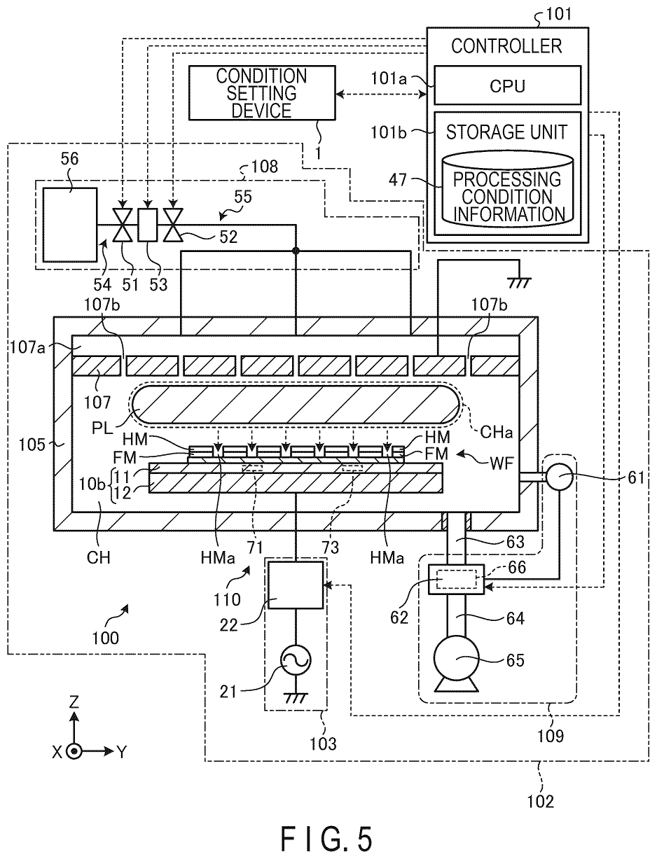

The condition setting device 1 illustrated in FIGS. 3 and 4 may be applied to the substrate processing apparatus 100 as illustrated in FIG. 5. FIG. 5 is a diagram illustrating the configuration of the substrate processing apparatus 100. FIG. 5 exemplifies a case in which the substrate processing to which the condition setting method is applied is dry etching and the substrate processing apparatus 100 to which the condition setting method is applied is a plasma processing apparatus. FIG. 5 exemplifies a parallel-plate type plasma processing apparatus, but the substrate processing apparatus 100 to which the condition setting method is applied may be a plasma processing apparatus of another type such as an ICP (Inductive Coupling Plasma) type plasma processing apparatus or an ECR (Electron Cyclotron Resonance) type plasma processing apparatus. FIG. 5 assumes a direction vertical to a surface of a working substrate WF as a Z direction, and two directions vertical to the Z direction and orthogonal to each other in a plane as an X direction and a Y direction.

The substrate processing apparatus 100 illustrated in FIG. 5 includes a substrate processing unit 102, the condition setting device 1, and the controller 101. The substrate processing unit 102 includes a power supply 103, a treatment container 105, a lower electrode 106, an upper electrode 107, a gas flow rate adjusting section 108, a pressure adjusting section 109, and a temperature adjusting section 110.

The treatment container 105 forms a treatment chamber CH. The treatment container 105 is configured to allow process gas to be supplied from the gas flow rate adjusting section 108 to the treatment chamber CH and configured to allow the treated process gas to be discharged from the treatment chamber CH to the pressure adjusting section 109.

The lower electrode 106 is disposed on a −Z side in the treatment chamber CH to be insulated from the treatment container 105 with an insulating material (not illustrated) in between. The working substrate WF such as a silicon wafer is placed on the lower electrode 106.

The lower electrode 106 includes a stage 11 and an electrode section 12. The stage 11 includes, for example, an electrostatic chuck (ESC: Electro Static Chuck) mechanism and holds the working substrate WF by using the electrostatic chuck mechanism. The temperature of the stage 11 is adjusted by the temperature adjusting section 110 under the control of the controller 101. The temperature adjusting section 110 hereby adjusts the temperature of the working substrate WF through the stage 11. The electrode section 12 is supplied with power from the power supply 103 and supplies the power to the working substrate WF through the stage 11. The stage 11 and the electrode section 12 may be each formed by using, for example, metal such as stainless steel or aluminum or non-metal such as ceramics.

The upper electrode 107 is disposed on a +Z side in the treatment chamber CH. The upper electrode 107 is connected to a ground potential. The treatment chamber CH includes a diffusion chamber 107a. The diffusion chamber 107a is surrounded by the upper electrode 107, and the upper wall and the side walls of the treatment container 105. The upper electrode 107 has a plurality of through holes 107b each extending through the upper electrode 107 from the diffusion chamber 107a to the treatment chamber CH in the Z direction.

The power supply 103 supplies electricity to the lower electrode 106 disposed on the −Z side in the treatment chamber CH. Specifically, the power supply 103 includes a high-frequency power supply 21, a matching box 22, and a blocking capacitor (not illustrated). The high-frequency power supply 21 generates high-frequency power and applies a bias voltage to the lower electrode 106 through the blocking capacitor under the control of the controller 101 when impedance matching is achieved by the matching box 22.

The gas flow rate adjusting section 108 adjusts the rate of each process gas to be supplied to the treatment chamber CH (the flow rate of each process gas to be supplied to the treatment chamber CH). Specifically, the gas flow rate adjusting section 108 includes a gas supply pipe 54, an on-off valve 51, a flow rate controller (MFC: Mass Flow Controller) 53, an on-off valve 52, a gas supply pipe 55, and a gas cylinder 56. The gas supply pipe 54 is supplied with process gas from the gas cylinder 56. The on-off valve 51, the flow rate controller 53, and the on-off valve 52 are each controlled by the controller 101. When the on-off valves 51 and 52 open at a predetermined timing, the flow rate controller 53 hereby controls the flow rate of process gas supplied from the gas cylinder 56 through the gas supply pipe 54 at a predetermined timing and supplies the process gas to the treatment chamber CH through the gas supply pipe 55.

The pressure adjusting section 109 has an auto pressure adjusting (APC: Auto Pressure Controller) function and adjusts the rate of process gas to be discharged, thereby controlling the pressure of the treatment chamber CH. Specifically, the pressure adjusting section 109 includes a pressure sensor 61, an exhaust gas pipe 63, a pressure controller 62, an exhaust gas pipe 64, and a vacuum pump 65. The pressure sensor 61 senses the pressure of the treatment chamber CH and supplies information about the value of the pressure to the pressure controller 62. The pressure controller 62 is connected to the treatment chamber CH through the exhaust gas pipe 63 and connected to the vacuum pump 65 through the exhaust gas pipe 64. The pressure controller 62 includes an adjusting valve 66 for which it is possible to adjust the degree to which the adjusting valve 66 is opened. The pressure controller 62 adjusts the degree to which the adjusting valve 66 is opened under the control of the controller 101 depending on the value of the pressure supplied from the pressure sensor 61 such that the pressure of the treatment chamber CH reaches a target value. The controller 101 hereby controls the pressure of the treatment chamber CH by using the rate of process gas to be discharged.

The temperature adjusting section 110 adjusts the temperature of the working substrate WF through the stage 11. Specifically, the temperature adjusting section 110 includes a temperature sensor 71 and a temperature adjuster (e.g., a heater or a cooler) 73 disposed in the stage 11. The temperature sensor 71 senses the temperature of the stage 11. The temperature sensor 71 supplies information about the sensed temperature to the controller 101. The controller 101 controls the temperature adjuster 73 such that the temperature of the stage 11 reaches target temperature. The controller 101 hereby controls the temperature of the working substrate WF through the stage 11.

The condition setting device 1 is capable of exchanging information with the controller 101. When the construction of processing conditions by the optimization unit 3 is completed, the output unit 5 outputs the constructed processing conditions for the multiple steps to the controller 101 in the condition setting device 1. The output unit 5 may output the processing condition information 43 to the controller 101.

The controller 101 is control circuit that includes a CPU 101a and a storage unit 101b. The CPU 101a integrally controls the respective units of the controller 101. The storage unit 101b is capable of storing predetermined information.

The CPU 101a of the controller 101 is programmed to perform the functions of a power supply control section, a gas flow rate control section, a pressure control section, and a temperature control section. The power supply control section controls the power supply 103 such that power for processing the working substrate WF reaches a target value. The gas flow rate control section controls the gas flow rate adjusting section 108 such that the rate of process gas to be supplied to the treatment chamber CH reaches a target value. The pressure control section controls the pressure adjusting section 109 such that the pressure of the treatment chamber CH reaches a target value. The temperature control section controls the temperature adjusting section 110 such that the temperature of the stage 11 reaches a target value.

The CPU 101a of the controller 101 integrally controls the power supply control section, the gas flow rate control section, the pressure control section, and the temperature control section. The storage unit 101b stores the processing condition information 43. The processing condition information 43 includes information about the order of processing conditions and the content (such as the gas flow rate, the pressure, the temperature, or the electricity) of each of the processing conditions for performing continuous processing while switching a processing condition for each of the multiple steps. The CPU 101a transmits instructions including the target values to the gas flow rate control section, the pressure control section, the temperature control section, and the power supply control section of the controller 101 in accordance with the respective processing conditions of the processing condition information 43 stored in the storage unit 101b and the power supply levels. This performs the continuous processing in the respective multiple steps.

When obtaining the processing condition information 47 from the condition setting device 1, the CPU 101a stores the processing condition information 43 in the storage unit 101b. It is to be noted that the CPU 101a may obtain the pieces of unmerged search solution information 44 to 46 from the condition setting device 1 and store the pieces of search solution information 44 to 46 in the storage unit 101b. The CPU 101a controls the gas flow rate control section, the pressure control section, and the temperature control section for the respective multiple steps in accordance with the processing condition information 47 and adjusts the gas flow rate, the pressure of the treatment chamber CH, and the substrate temperature. The CPU 101a controls the power supply control section for each of the multiple steps in accordance with the processing condition information 47, adjusts the power supply electricity to be supplied from the power supply 103 to the lower electrode 106, and forms an electric field between the upper electrode 107 and the lower electrode 106 in the treatment chamber CH.

The substrate processing apparatus 100 hereby generates plasma PL of process gas in a space CHa separated from the lower electrode 106 in the treatment chamber CH on the +Z side under a processing condition for each of the multiple steps in accordance with the processing condition information 47 and ionizes the process gas. In addition, under the processing condition for each of the multiple steps, the ions of the process gas are accelerated toward a working film FM on the working substrate WF by an electric field in a −Z direction as illustrated by a dotted arrow.

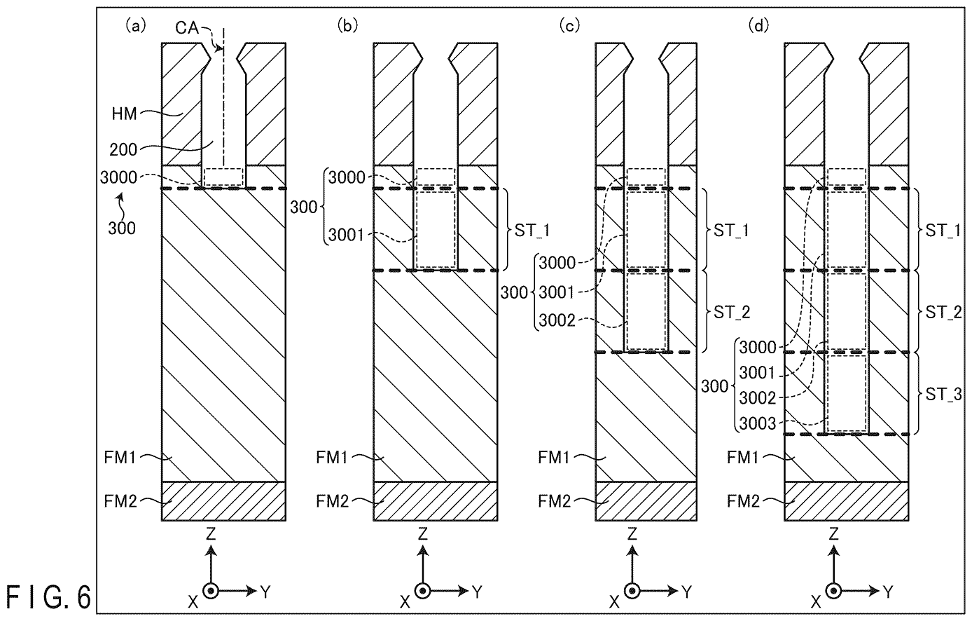

The working substrate WF is irradiated with ions by using a hard mask HM as an etching mask. As illustrated in FIG. 6, the working film FM is hereby subjected, for example, to etching treatment for a hole pattern 300 corresponding to a hole pattern 200 of the hard mask HM. The part (a) of FIG. 6 to the part (d) of FIG. 6 are YZ cross-sectional views of the respective multiple steps. FIG. 6 exemplifies processed cross-sectional shapes for the one hole pattern 300 for the sake of simplification.

The aspect ratio of the processed cross-sectional shape of the hole pattern 300 by multistep dry etching changes during processing as illustrated in the part (a) of FIG. 6 to the part (d) of FIG. 6. The ratio between ions and radicals reaching the processed sections or the like changes accordingly.

Accordingly, the whole of the process of the processing by the dry etching may be divided into an initial step illustrated in the part (a) of FIG. 6, step ST_1 illustrated in the part (b) of FIG. 6, step ST_2 illustrated in the part (c) of FIG. 6, and step ST_3 illustrated in the part (d) of FIG. 6.

A treated portion 3000 in the initial step in the hole pattern 300 has a relatively lower ratio of the depth in the Z direction to the width in an XY direction. An aspect ratio AR0 in the initial step is relatively low.

In step ST_1, a treated portion 3001 is added to the hole pattern 300 in addition to the treated portion 3000. The total treated portion of the treated portion 3000 and the treated portion 3001 has a higher ratio of the depth in the Z direction to the width in the XY direction than in the initial step. An aspect ratio AR1 of the hole pattern 300 in step ST_1 is higher than the aspect ratio AR0 in the initial step.

In step ST_2, a treated portion 3002 is added to the hole pattern 300 in addition to the treated portion 3000 and the treated portion 3001. The total treated portion of the treated portion 3000, the treated portion 3001, and the treated portion 3002 has a higher ratio of the depth in the Z direction to the width in the XY direction than in step ST_1. An aspect ratio AR2 of the hole pattern 300 in step ST_2 is higher than the aspect ratio AR1 in step ST_1.

In step ST_3, a treated portion 3003 is added to the hole pattern 300 in addition to the treated portion 3000, the treated portion 3001, and the treated portion 3002. The total treated portion of the treated portion 3000, the treated portion 3001, the treated portion 3002, and the treated portion 3003 has a higher ratio of the depth in the Z direction to the width in the XY direction than in step ST_2. An aspect ratio AR3 of the hole pattern 300 in step ST_3 is higher than the aspect ratio AR2 in step ST_2.

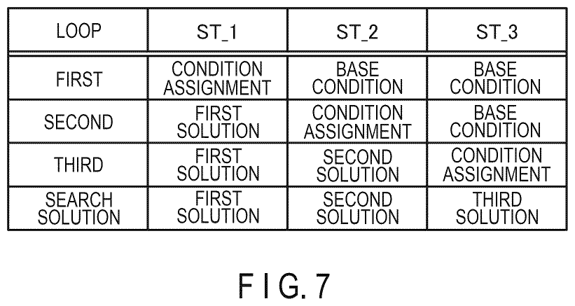

When the chronological changes of the aspect ratios AR1 to AR3 in the plurality of steps ST_1 to ST_3 are taken into consideration, the processing conditions may be optimized (S3) in a procedure as illustrated in FIG. 7. FIG. 7 is a diagram illustrating a procedure of optimizing a processing condition for each of the multiple steps.

To optimize a processing condition (S3), a loop of S4 to S9 is repeated.

In the first loop, as illustrated in FIG. 7, a condition is assigned for step ST_1 and base conditions are adopted for steps ST_2 and ST_3. That is, step ST_1 is selected as a step of interest (S4) and one or more candidate processing conditions are generated as processing conditions for step ST_1 in addition to a base condition (S5). At this time, the processing conditions for steps ST_2 and ST_3 are the base conditions.

A plurality of parameters relating to a processed shape is predicted under each of the base condition and the one or more candidate processing conditions for step ST_1 (S6). A plurality of parameters relating to a processed shape obtained in a case in which any of processing conditions for steps ST_1, ST_2, and ST_3 is the base condition is predicted. A plurality of parameters relating to the processed shapes obtained in a case in which the processing conditions for steps ST_1, ST_2, and ST_3 are a candidate processing condition, the base condition, and the base condition, respectively, is predicted.

Depending on the plurality of parameters, some of the one or more candidate processing conditions for step ST_1 are excluded (S7). Some candidate processing conditions excluded here are candidate processing conditions that do not each satisfy the predetermined condition.

In a case in which the plurality of parameters includes a first parameter and a second parameter, a candidate processing condition under which at least one of the first parameter and the second parameter deteriorates more than under the reference processing condition may be excluded as a candidate processing condition that does not satisfy the predetermined condition.

Alternatively, in a case in which the plurality of parameters includes a first parameter and a second parameter, a candidate processing condition under which at least one of the first parameter and the second parameter is improved more than under the reference processing condition and the other deteriorates more than under the reference processing condition may be excluded as a candidate processing condition under which the processed shape is traded off.

Alternatively, in a case in which the plurality of parameters includes a first parameter and a second parameter, a candidate processing condition under which the amount by which at least one of the first parameter and the second parameter deteriorates more than under the reference processing condition exceeds a threshold may be excluded as a candidate processing condition that does not satisfy the predetermined condition.

Alternatively, in a case in which the plurality of parameters includes a first parameter and a second parameter, a candidate processing condition under which at least one of the first parameter and the second parameter falls out of a permissible range and deteriorates more than under the reference processing condition may be excluded as a candidate processing condition that does not satisfy the predetermined condition.

One of one or more processing conditions left after the exclusion of the base condition and the one or more candidate processing conditions for step ST_1 is selected as the first solution (S8).

If the plurality of parameters of each of the steps does not converge in the permissible ranges (No in S9), the second loop is carried out.

In the second loop, as illustrated in FIG. 7, a condition is assigned for step ST_2 and the first solution and the base condition are respectively adopted for steps ST_1 and ST_3. That is, step ST_2 is selected as a step of interest (S4) and one or more candidate processing conditions are generated as processing conditions for step ST_2 in addition to the base condition (S5). At this time, the processing conditions for steps ST_1 and ST_3 are the first solution and the base condition, respectively.

A plurality of parameters relating to a processed shape is predicted under each of the base condition and the one or more candidate processing conditions for step ST_2 (S6). A plurality of parameters relating to the processed shapes obtained in a case in which the processing conditions for steps ST_1, ST_2, and ST_3 are the first solution, the base condition, and the base condition, respectively, is predicted. A plurality of parameters relating to the processed shapes obtained in a case in which the processing conditions for steps ST_1, ST_2, and ST_3 are the first solution, a candidate processing condition, and the base condition, respectively, is predicted.

Depending on the plurality of parameters, some of the one or more candidate processing conditions for step ST_2 are excluded (S7).

In a case in which the plurality of parameters includes a first parameter and a second parameter, a candidate processing condition under which at least one of the first parameter and the second parameter deteriorates more than under the base condition may be excluded as a candidate processing condition that does not satisfy the predetermined condition.

Alternatively, in a case in which the plurality of parameters includes a first parameter and a second parameter, a candidate processing condition under which at least one of the first parameter and the second parameter is improved more than under the reference processing condition and the other deteriorates more than under the reference processing condition may be excluded as a candidate processing condition under which the two or more parameters are traded off relating to the processed shape.

Alternatively, in a case in which the plurality of parameters includes a first parameter and a second parameter, a candidate processing condition under which the amount by which at least one of the first parameter and the second parameter deteriorates more than under the base condition exceeds a threshold may be excluded as a candidate processing condition that does not satisfy the predetermined condition.

Alternatively, in a case in which the plurality of parameters includes a first parameter and a second parameter, a candidate processing condition under which at least one of the first parameter and the second parameter falls out of a permissible range and deteriorates more than under the base condition may be excluded as a candidate processing condition that does not satisfy the predetermined condition.

In a case in which the plurality of parameters includes a first parameter and a second parameter, a candidate processing condition under which at least one of the first parameter and the second parameter falls out of a permissible range and deteriorates more than under the base condition may be excluded as a candidate processing condition that does not satisfy the predetermined condition.

One of one or more processing conditions left after the exclusion of the base condition and the one or more candidate processing conditions for step ST_2 is selected as the second solution (S8).

If the plurality of parameters of each of the steps does not converge in the permissible ranges (No in S9), the third loop is carried out.

In the third loop, as illustrated in FIG. 7, a condition is assigned for step ST_3 and the first solution and the second solution are respectively adopted for steps ST_1 and ST_2. That is, step ST_3 is selected as a step of interest (S4) and one or more candidate processing conditions are generated as processing conditions for step ST_3 in addition to the base condition (S5). At this time, the processing conditions for steps ST_1 and ST_2 are the first solution and the second solution, respectively.

A plurality of parameters relating to a processed shape is predicted under each of the base condition and the one or more candidate processing conditions for step ST_3 (S6). A plurality of parameters relating to the processed shapes obtained in a case in which the processing conditions for steps ST_1, ST_2, and ST_3 are the first solution, the second solution, and the base condition, respectively, is predicted. A plurality of parameters relating to the processed shapes obtained in a case in which the processing conditions for steps ST_1, ST_2, and ST_3 are the first solution, the second solution, and a candidate processing condition, respectively, is predicted.

Depending on the plurality of parameters, some of the one or more candidate processing conditions for step ST_3 are excluded (S7).

In a case in which the plurality of parameters includes a first parameter and a second parameter, a candidate processing condition under which at least one of the first parameter and the second parameter deteriorates more than under the base condition may be excluded as a candidate processing condition that does not satisfy the predetermined condition.

Alternatively, in a case in which the plurality of parameters includes a first parameter and a second parameter, a candidate processing condition under which at least one of the first parameter and the second parameter is improved more than under the reference processing condition and the other deteriorates more than under the reference processing condition may be excluded as a candidate processing condition under which the two or more parameters are traded off relating to the processed shape.

Alternatively, in a case in which the plurality of parameters includes a first parameter and a second parameter, a candidate processing condition under which the amount by which at least one of the first parameter and the second parameter deteriorates more than under the base condition exceeds a threshold may be excluded as a candidate processing condition that does not satisfy the predetermined condition.

Alternatively, in a case in which the plurality of parameters includes a first parameter and a second parameter, a candidate processing condition under which at least one of the first parameter and the second parameter falls out of a permissible range and deteriorates more than under the base condition may be excluded as a candidate processing condition that does not satisfy the predetermined condition.

One of one or more processing conditions left after the exclusion of the base condition and the one or more candidate processing conditions for step ST_3 is selected as the third solution (S8).

If the plurality of parameters of each of the steps converges in the permissible ranges (Yes in S9), the respective processing conditions for steps ST_1, ST_2, and ST_3 of the multiple steps are used as search solutions at the first solution, the second solution, and the third solution and the condition setting processing (S1) is completed.

As described above, in the embodiment, the optimization of assigning a processing condition in a step of interest and using the processing condition as a temporary processing condition in another step to improve a processed shape while sequentially shifting the step of interest among the multiple steps from the first step to the last step is repeated in the condition setting method. This makes it possible to optimize the processing conditions for the respective multiple steps while taking into consideration the chronological influence of the respective steps and efficiently set the processing conditions for the respective steps.

It is to be noted that the processing conditions may be repeatedly optimized (S3) as a first modification example of the embodiment while a cycle of sequentially shifting a step of interest from the first step to the last step is carried out a plurality of times.

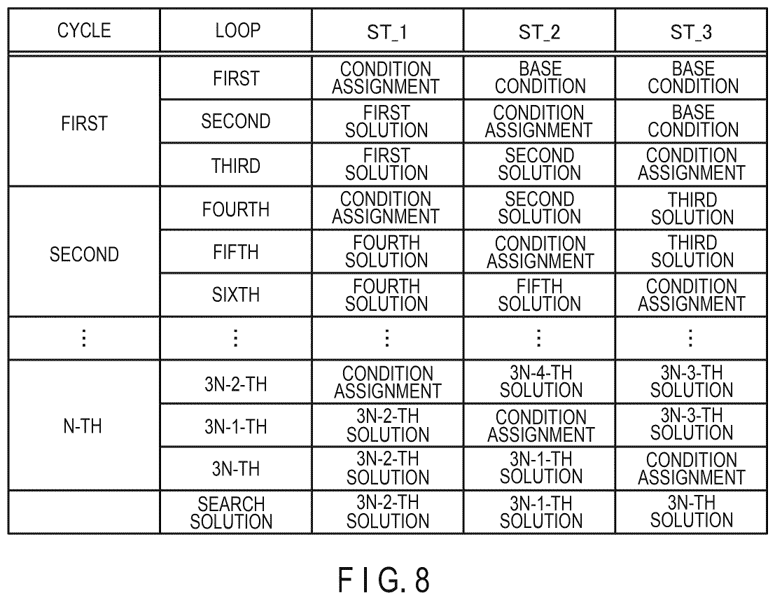

For example, the processing conditions may be optimized (S3) in a procedure as illustrated in FIG. 8. FIG. 8 is a diagram illustrating a procedure of optimizing a processing condition for each of multiple steps in the first modification example of the embodiment. FIG. 8 exemplifies a case in which a cycle is carried out N times. N represents any integer greater than or equal to 2.

In the first cycle illustrated in FIG. 8, the first to third loops may be carried out. The first to third loops may be carried out as with the first to third loops illustrated in FIG. 7.

If a plurality of parameters for each of the steps does not converge in the permissible ranges after the first cycle comes to an end (No in S9), the second cycle is carried out.

In the second cycle, the fourth to sixth loops may be carried out.

In the fourth loop, as illustrated in FIG. 8, a condition is assigned for step ST_1 and the second solution and the third solution are respectively adopted for steps ST_2 and ST_3.

In other words, step ST_1 is selected as a step of interest (S4) and one or more candidate processing conditions are generated as processing conditions for step ST_1 in addition to the first solution (S5). At this time, the processing conditions for steps ST_2 and ST_3 are the second solution and the third solution, respectively.

A plurality of parameters relating to a processed shape is predicted under each of the first solution and the one or more candidate processing conditions for step ST_1 (S6). Depending on the plurality of parameters, some of the one or more candidate processing conditions for step ST_1 are excluded (S7). One of one or more processing conditions left after the exclusion of the first solution and the one or more candidate processing conditions for step ST_1 is selected as the fourth solution (S8).

If the plurality of parameters of each of the steps does not converge in the permissible ranges (No in S9), the fifth loop is carried out.

In the fifth loop, as illustrated in FIG. 8, a condition is assigned for step ST_2 and the fourth solution and the third solution are respectively adopted for steps ST_1 and ST_3.

In other words, step ST_2 is selected as a step of interest (S4) and one or more candidate processing conditions are generated as processing conditions for step ST_2 in addition to the second solution (S5). At this time, the processing conditions for steps ST_1 and ST_3 are the fourth solution and the third solution, respectively.

A plurality of parameters relating to a processed shape is predicted under each of the second solution and the one or more candidate processing conditions for step ST_2 (S6). Depending on the plurality of parameters, some of the one or more candidate processing conditions for step ST_2 are excluded (S7). One of one or more processing conditions left after the exclusion of the second solution and the one or more candidate processing conditions for step ST_2 is selected as the fifth solution (S8).

If the plurality of parameters of each of the steps does not converge in the permissible ranges (No in S9), the sixth loop is carried out.

In the sixth loop, as illustrated in FIG. 8, a condition is assigned for step ST_3 and the fourth solution and the fifth solution are respectively adopted for steps ST_1 and ST_2.

In other words, step ST_3 is selected as a step of interest (S4) and one or more candidate processing conditions are generated as processing conditions for step ST_3 in addition to the third solution (S5). At this time, the processing conditions for steps ST_1 and ST_2 are the fourth solution and the fifth solution, respectively.

A plurality of parameters relating to a processed shape is predicted under each of the third solution and the one or more candidate processing conditions for step ST_3 (S6). Depending on the plurality of parameters, some of the one or more candidate processing conditions for step ST_2 are excluded (S7). One of one or more processing conditions left after the exclusion of the third solution and the one or more candidate processing conditions for step ST_2 is selected as the sixth solution (S8).

If a plurality of parameters for each of the steps does not converge in the permissible ranges after the second cycle comes to an end (No in S9), the third cycle is carried out.

In the third cycle, the seventh to ninth loops may be carried out.

If a plurality of parameters for each of the steps does not converge in the permissible ranges after the N−1-th cycle comes to an end (No in S9), the N-th cycle is carried out.

In the N-th cycle, the 3N−2-th to 3N-th loops may be carried out.

In the 3N−2-th loop, as illustrated in FIG. 8, a condition is assigned for step ST_1 and the 3N−4-th solution and the 3N−3-th solution are respectively adopted for steps ST_2 and ST_3.

In other words, step ST_1 is selected as a step of interest (S4) and one or more candidate processing conditions are generated as processing conditions for step ST_1 in addition to the 3N−5-th solution (S5). At this time, the processing conditions for steps ST_2 and ST_3 are the 3N−4-th solution and the 3N−3-th solution, respectively.

A plurality of parameters relating to a processed shape is predicted under each of the 3N−5-th solution and the one or more candidate processing conditions for step ST_1 (S6). Depending on the plurality of parameters, some of the one or more candidate processing conditions for step ST_1 are excluded (S7). One of one or more processing conditions left after the exclusion of the 3N−5-th solution and the one or more candidate processing conditions for step ST_1 is selected as the 3N−2-th solution (S8).

If the plurality of parameters of each of the steps does not converge in the permissible ranges (No in S9), the 3N−1-th loop is carried out.

In the 3N−1-th loop, as illustrated in FIG. 8, a condition is assigned for step ST_2 and the 3N−2-th solution and the 3N−3-th solution are respectively adopted for steps ST_1 and ST_3.

In other words, step ST_2 is selected as a step of interest (S4) and one or more candidate processing conditions are generated as processing conditions for step ST_2 in addition to the 3N−4-th solution (S5). At this time, the processing conditions for steps ST_1 and ST_3 are the 3N−2-th solution and the 3N−3-th solution, respectively.

A plurality of parameters relating to a processed shape is predicted under each of the 3N−4-th solution and the one or more candidate processing conditions for step ST_2 (S6). Depending on the plurality of parameters, some of the one or more candidate processing conditions for step ST_2 are excluded (S7). One of one or more processing conditions left after the exclusion of the 3N−4-th solution and the one or more candidate processing conditions for step ST_2 is selected as the 3N−1-th solution (S8).

If the plurality of parameters of each of the steps does not converge in the permissible ranges (No in S9), the 3N-th loop is carried out.

In the 3N-th loop, as illustrated in FIG. 8, a condition is assigned for step ST_3 and the 3N−2-th solution and the 3N−1-th solution are respectively adopted for steps ST_1 and ST_2.

In other words, step ST_3 is selected as a step of interest (S4) and one or more candidate processing conditions are generated as processing conditions for step ST_3 in addition to the 3N−3-th solution (S5). At this time, the processing conditions for steps ST_1 and ST_2 are the 3N−2-th solution and the 3N−1-th solution, respectively.

A plurality of parameters relating to a processed shape is predicted under each of the 3N−3-th solution and the one or more candidate processing conditions for step ST_3 (S6). Depending on the plurality of parameters, some of the one or more candidate processing conditions for step ST_2 are excluded (S7). One of one or more processing conditions left after the exclusion of the 3N−3-th solution and the one or more candidate processing conditions for step ST_2 is selected as the 3N-th solution (S8).

If the plurality of parameters of each of the steps converges in the permissible ranges after the N-th cycle comes to an end (Yes in S9), the respective processing conditions for steps ST_1, ST_2, and ST_3 of the multiple steps are used as search solutions at the 3N−2-th solution, the 3N−1-th solution, and the 3N-th solution and the condition setting processing (S1) is completed.

In this way, in the condition setting method, the optimization of processing conditions is repeated while a cycle of sequentially shifting the step of interest among the multiple steps from the first step to the last step is carried out a plurality of times. This also makes it possible to optimize the processing conditions for the respective multiple steps while taking into consideration the chronological influence of the respective steps and efficiently set the processing conditions for the respective steps.

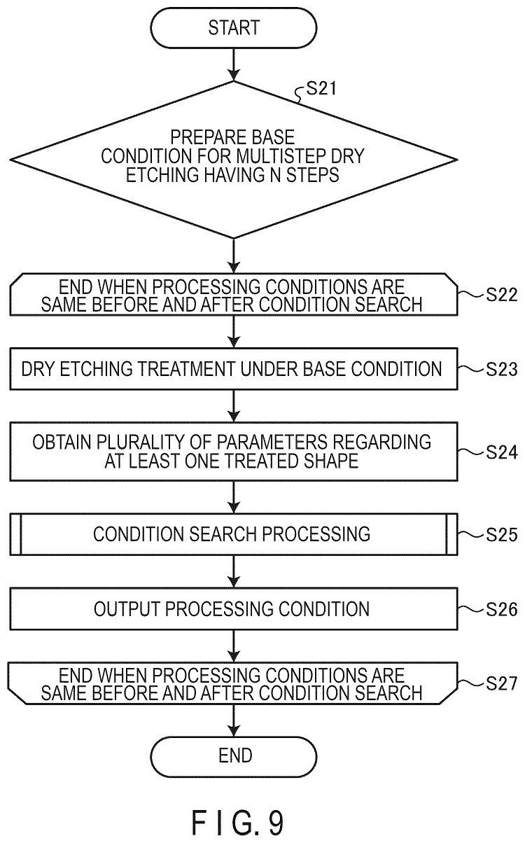

Alternatively, the condition setting processing (S1) may be performed as illustrated in FIG. 9 as a second modification example of the embodiment. FIG. 9 is a flowchart illustrating the condition setting processing (S1). FIG. 9 exemplifies the condition setting processing (S1) for a case in which the substrate processing is dry etching.

A base condition for multistep dry etching including N steps is prepared (S21).

In the multistep dry etching, for example, a process of dry etching for a hole pattern is divided into the N steps that include steps ST_1 to ST_N.

The base condition includes conditions relating to default power supply electricity, a default process gas flow rate, default treatment chamber pressure, default substrate temperature, and the like.

A loop of S22 to S27 is carried out. The loop of S22 to S27 is repeated until the N steps each result in the same processing before and after condition search processing (S25).

A treated shape obtained in a case in which dry etching treatment is conducted with the processing in each of the N steps complying with the base condition is simulated (S23).

The treated shape includes a treated cross-sectional shape and a treated planar shape.

Simulations may be obtained for N types of treated shapes corresponding to steps ST_1 to ST_N. The simulations may be obtained by using a learned model subjected to machine learning to output a treated shape depending on a processing condition or by using an expression such as a function that expresses a treated shape corresponding to a processing condition. A plurality of parameters relating to at least one treated shape is hereby obtained for the base condition in each of steps ST_1 to ST_N (S24).

The plurality of parameters is each used to evaluate the degree of optimization of a treated shape. The permissible range of each of the plurality of parameters may be experimentally determined in advance.

For example, the plurality of parameters includes parameters relating to the upper blockage rate of a treated cross-sectional shape, the degree of bowing of a treated cross-sectional shape, the degree of twisting of a treated cross-sectional shape, the bottom blockage rate of a treated cross-sectional shape, the degree of distortion of a treated planar shape, an etching rate, and the like.

The parameter relating to the upper blockage rate of a treated cross-sectional shape includes the degree to which the upper side surface is blocked with respect to the reference side surface (e.g., cylindrical surface) of a hole pattern.

The parameter relating to the degree of bowing of a treated cross-sectional shape includes the degree to which the middle side surface expands outward with respect to the reference side surface of the hole pattern.

The parameter relating to the degree of twisting of a treated cross-sectional shape includes the degree to which the distance between the side surfaces from the middles to the bottoms varies between adjacent hole patterns and the degree to which the central axis of the side surface from the middle to the bottom is tilted with respect to the central axis of the reference side surface of the hole pattern.

The parameter relating to the bottom blockage rate of a treated cross-sectional shape includes the degree to which the bottom side surface is blocked with respect to the reference side surface of a hole pattern.

The parameter relating to the degree of distortion of a treated planar shape includes the degree to which a hole pattern is distorted with respect to a reference planar shape.

In response to a treated shape being obtained (S24), the condition search processing (S25) is performed and a processing condition for each of the multiple steps is constructed.

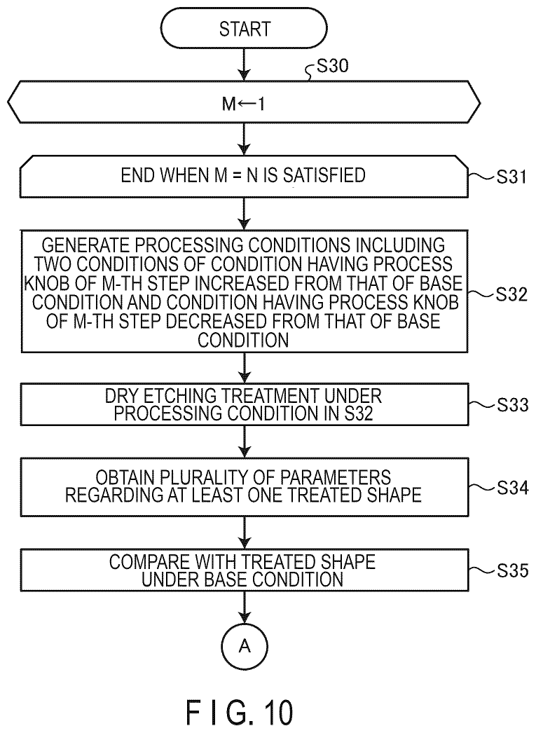

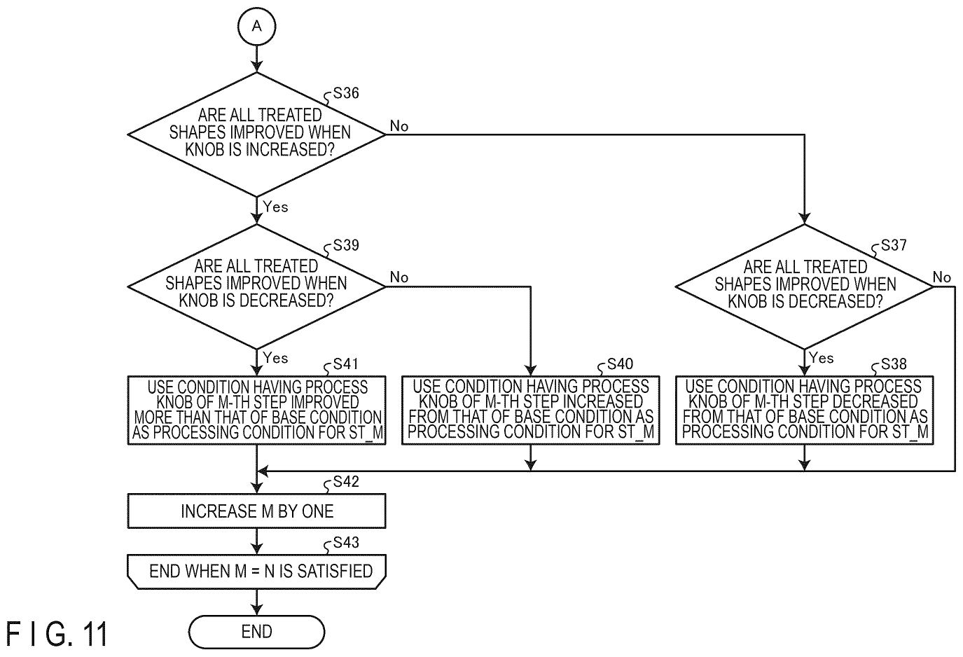

In the condition search processing (S25), S30 to S43 illustrated in FIGS. 10 and 11 may be performed. Each of FIGS. 10 and 11 is a flowchart illustrating the condition search processing (S25) in the second modification example of the embodiment.

When an initial value of 1 is set for a parameter M (S30), a loop of S31 to S43 is executed. The loop of S31 to S43 is repeated until M=N is satisfied. N represents the number of steps ST included in the multiple steps.

In the loop of S31 to S43, processing conditions including a condition having the process knob of the M-th step of the multiple steps increased from that of the base condition and a condition having the process knob of the M-th step of the multiple steps decreased from that of the base condition are created (S32). At this time, each of processing conditions for other steps ST_1 to ST_M−1 and ST_M+1 to ST_N of the multiple steps is a reference processing condition (e.g., a base condition or an optimized processing condition).

The condition having the process knob increased from that of the base condition includes, for example, conditions relating to power supply electricity more than the default power supply electricity, a gas flow rate higher than the default process gas flow rate, treatment chamber pressure higher than the default treatment chamber pressure, substrate temperature higher than the default substrate temperature, and the like.

The condition having the process knob decreased from that of the base condition includes, for example, conditions relating to power supply electricity less than the default power supply electricity, a gas flow rate lower than the default process gas flow rate, treatment chamber pressure lower than the default treatment chamber pressure, substrate temperature lower than the default substrate temperature, and the like.

A treated shape obtained in a case in which dry etching treatment is conducted under a processing condition for S32 is simulated for the multiple steps (S33).

Simulations may be obtained for N types of treated shapes corresponding to steps ST_1 to ST_N. A plurality of parameters relating to at least one treated shape is hereby obtained for the processing condition for S32 in each of steps ST_1 to ST_N (S34).

The treated shape in S34 is compared with the treated shape under the base condition (S35). The treated shape obtained in S24 is used as the treated shape under the base condition. For the N types of treated shapes corresponding to steps ST_1 to ST_N, the treated shape under the processing condition for S32 is compared with the treated shape under the base condition.

When the process knob is increased depending on a result of the comparison (S35), it is determined whether all the treated shapes in steps ST_1 to ST_N are improved (S36).

If all the treated shapes in steps ST_1 to ST_N are not improved when the process knob is increased (No in S36), it is determined whether all the treated shapes in steps ST_1 to ST_N are improved when the process knob is decreased (S37).

If all the treated shapes in steps ST_1 to ST_N are not improved when the process knob is decreased (No in S37), the processing advances to S42 on the assumption that the base condition is to be maintained as a processing condition for step ST_M.

If all the treated shapes in steps ST_1 to ST_N are improved when the process knob is decreased (Yes in S37), a condition having the process knob of the M-th step decreased from that of the base condition is used as a processing condition for step ST_M (S38).

If all the treated shapes in steps ST_1 to ST_N are improved when the process knob is increased (Yes in S36) and all the treated shapes in steps ST_1 to ST_N are not improved when the process knob is decreased (No in S39), a condition having the process knob of the M-th step increased from that of the base condition is used as a processing condition for step ST_M (S40).

If all the treated shapes in steps ST_1 to ST_N are improved when the process knob is increased (Yes in S36) and all the treated shapes in steps ST_1 to ST_N are improved when the process knob is decreased (Yes in S39), a condition having the process knob of the M-th step improved more than that of the base condition is used as a processing condition for step ST_M (S41).

After that, the parameter M is incremented (S42).

The loop of S31 to S43 comes to an end when M=N is satisfied. This brings the condition search processing (S25) to an end.

When the condition search processing (S25) comes to an end, the constructed processing condition is output (S26). In a case in which S21 to S25 are performed by the condition setting device 1 (see FIG. 3), the constructed processing conditions may be output from the condition setting device 1 to the controller 101.

The loop of S22 to S27 comes to an end when the N steps each result in the same processing before and after condition search processing (S25). This brings the condition setting processing (S1) to an end.

In this way, the optimization of assigning a processing condition in the M-th step and using the processing condition as a temporary processing condition in another step to improve a processed shape while sequentially shifting the M-th step of the multiple steps from the first step to the last step is repeated in the condition setting method. This also makes it possible to optimize the processing conditions for the respective multiple steps while taking into consideration the chronological influence of the respective steps and efficiently set the processing conditions for the respective steps.

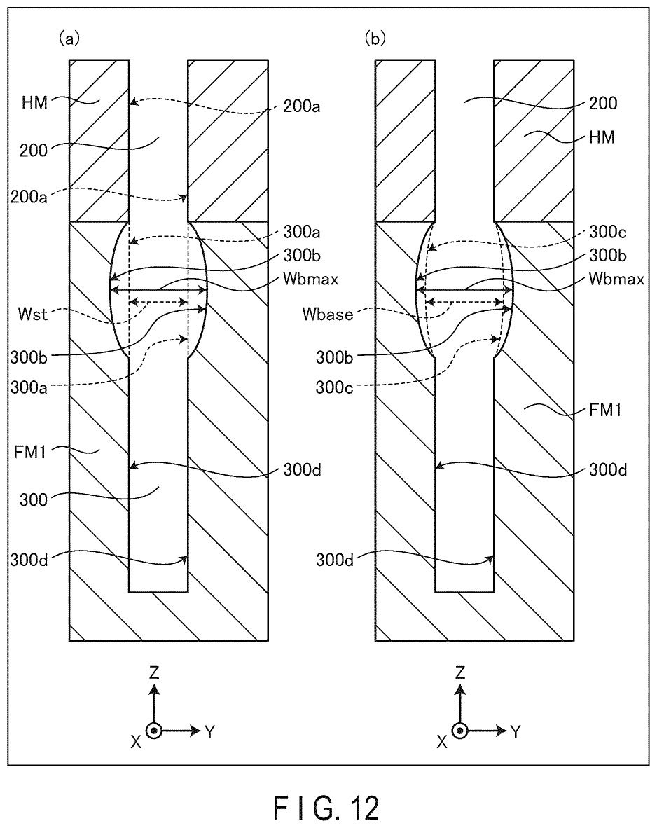

Alternatively, the plurality of parameters relating to a treated shape may be parameters as illustrated in FIGS. 12 to 14 as a third modification example of the embodiment. Each of FIGS. 12 to 14 is a diagram illustrating a parameter relating to a treated shape.

FIG. 12 exemplifies a parameter relating to the degree of bowing of a treated cross-sectional shape. The parameter relating to the degree of bowing of a treated cross-sectional shape includes the degree to which the middle side surface expands outward with respect to the reference side surface of the hole pattern.

The side surface of the hole pattern 300 includes, for example, a bowing portion 300b and a flat portion 300d as illustrated in the part (a) of FIG. 12. The bowing portion 300b is disposed between the side surface of the hole pattern 200 and the flat portion 300d in the Z direction. The flat portion 300d extends flatly in the Z direction. The bowing portion 300b extends in the Z direction while expanding outward in the XY direction more than the flat portion 300d.

The reference side surface of the hole pattern 300 may be an extension plane 300a obtained by extending the side surface of the hole pattern 200 in the hard mask HM toward the hole pattern 300 (−Z side). At this time, the extension plane 300a may be a substantially cylindrical plane. When Wbmax represents the maximum diameter of the bowing portion 300b on the side surface of the hole pattern 300 to be evaluated and Wst represents the diameter at a Z position corresponding to the bowing portion 300b in the extension plane 300a, a degree of bowing Ebowing may be defined by the following Expression 1.

$$Ebowing = ( Wb max ) / ( Wst ) \qquad Expression 1$$

It is preferable that the degree of bowing Ebowing defined by Expression 1 be 0.01 or less.

It is to be noted that a processing condition is not optimized in a case in which the absolute value, for example, Wst, of the diameter of the hole pattern on the reference side surface increases even though the degree of bowing Ebowing defined by Expression 1 is within a permissible range. Accordingly, the absolute value of the diameter of the hole pattern on the reference side surface may be used as a parameter. For example, it is preferable that the absolute value Wst of the diameter of the hole pattern on the reference side surface be 200 nm or less. It is more preferable that the absolute value Wst of the diameter of the hole pattern on the reference side surface be 150 nm or less. It is still more preferable that the absolute value Wst of the diameter of the hole pattern on the reference side surface be 100 nm or less.

Alternatively, the reference side surface of the hole pattern 300 may be, for example, a bowing portion 300c of the hole pattern 300 on the side surface obtained in a case in which dry etching is conducted under a base condition as illustrated in the part (b) of FIG. 12. When Wbmax represents the maximum diameter of the bowing portion 300b on the side surface of the hole pattern 300 to be evaluated and Wbase represents the maximum diameter of the bowing portion 300c under the base condition, the degree of bowing Ebowing may be defined by the following Expression 2.

$$Ebowing = ( Wb max ) / ( Wbase ) \qquad Expression 2$$

It is preferable that the degree of bowing Ebowing defined by Expression 2 be 0.01 or less.

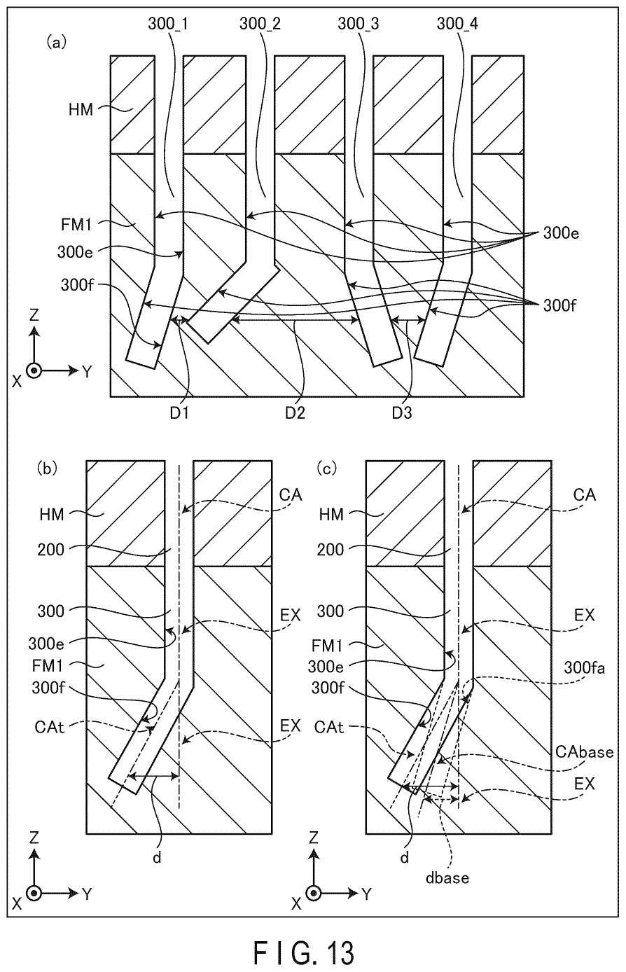

FIG. 13 exemplifies a parameter relating to the degree of twisting of a treated cross-sectional shape. The parameter relating to the degree of twisting of a treated cross-sectional shape includes the degree to which the distance between the side surfaces of adjacent hole patterns from the middles to the bottoms varies between the hole patterns and the degree to which the central axis of the side surface of a hole pattern from the middle to the bottom is tilted with respect to the central axis of the reference side surface of the hole pattern.

The side surface of the hole pattern 300 includes, for example, a flat portion 300e and a twisted portion 300f as illustrated in the part (a) of FIG. 13. The twisted portion 300f is disposed between the flat portion 300e and the bottom surface of the hole pattern 300 in the Z direction. The flat portion 300e extends flatly in the Z direction. As illustrated in the part (b) of FIG. 13, a central axis CAt of the twisted portion 300f is tilted more in the XY direction than the central axis of the flat portion 300e.

Twisting is a random phenomenon. The degree of twisting may be defined as the degree to which the distance between the twisted portions 300f varies between adjacent hole patterns.

For example, as illustrated in the part (a) of FIG. 13, it is possible to define the degree of twisting as the standard deviation of distances D1 between the side surfaces of the twisted portions 300f at the Z position at the end on the −Z side between adjacent hole patterns. When 300_1 to 300_n+1 represent the adjacent hole patterns and D1 to Dn represent the distances between the side surfaces of the twisted portions 300f, an average D⁻ thereof may be defined by the following Expression 3.

$${D}^{-} = \frac{1}{n} {\sum }_{i = 1}^{n} {D}_{i} \qquad Expression 3$$

A degree of twisting Etwisting may be defined by the following Expression 4 with the average D⁻.

$$Etwisting = \sqrt{\frac{1}{n} {\sum }_{i = 1}^{n} {( {D}_{i} - {D}^{-} )}^{2}} \qquad Expression 4$$

In the example of the part (a) of FIG. 13, 300_1 to 300_4 represent the adjacent hole patterns and D1 to D3 represent the distances between the side surfaces 300f from the middles to the bottoms. The average D⁻ is thus obtained in the following Expression 5 and the degree of twisting Etwisting is obtained in the following Expression 6.

$${D}^{-} = \frac{{D}_{1} + {D}_{2} + {D}_{3}}{3} \qquad Expression 5$$

$$Etwisting = \sqrt{\frac{{( {D}_{1} - {D}^{-} )}^{2} + {( {D}_{2} - {D}^{-} )}^{2} + {( {D}_{3} - {D}^{-} )}^{2}}{3}} \qquad Expression 6$$

Alternatively, the degree of twisting may be defined as the degree to which the central axis of the twisted portion 300f is tilted with respect to the central axis of the reference side surface of a hole pattern.

For example, as illustrated in the part (b) of FIG. 13, the central axis of the reference side surface of the hole pattern may be a central axis EX obtained by extending a central axis CA of the side surface of the hole pattern 200 in the hard mask HM toward the hole pattern 300 (−Z side).

For example, as illustrated in the part (b) of FIG. 13, it is possible to define the degree of twisting as the distance between the twisted portions 300f at the Z position at the end on the −Z side. When d represents the distance from the central axis CAt of the twisted portion 300f at the Z position at the end of the twisted portion 300f on the −Z side to the central axis EX, the degree of twisting Etwisting may be defined by the following Expression 7.

$$Etwisting = d \qquad Expression 7$$

It is preferable that the degree of twisting Etwisting defined by Expression 7 be as close to 0 as possible.

Alternatively, although not illustrated, it is possible to define the degree of twisting, for example, as the standard deviation of the distances d from the central axes CAt of the twisted portions 300f to the central axes EX between adjacent hole patterns. When 300_1 to 300_n+1 represent the adjacent hole patterns and d1 to dn represent the distances from the central axes CAt of the twisted portions 300f to the central axes EX, an average d⁻ thereof may be defined by the following Expression 8.

$${d}^{-} = \frac{1}{n} {\sum }_{i = 1}^{n} {d}_{i} \qquad Expression 8$$

The degree of twisting Etwisting may be defined by the following Expression 9 with the average d⁻.

$$Etwisting = \sqrt{\frac{1}{n} {\sum }_{i = 1}^{n} {( {d}_{i} - {d}^{-} )}^{2}} \qquad Expression 9$$

Alternatively, the central axis of the reference side surface of the hole pattern may be, for example, a central axis CAbase of a twisted portion 300fa of the hole pattern 300 on the side surface obtained in a case in which dry etching is conducted under a base condition as illustrated in the part (c) of FIG. 13. When d represents the distance from the central axis CAt of the twisted portion 300f to be evaluated at the Z position at the end of the twisted portion 300f on the −Z side to the central axis EX and dbase represents the distance from the central axis CAbase of the twisted portion 300fa at the Z position at the end of the twisted portion 300fa under the base condition on the −Z side to the central axis EX, the degree of twisting Etwisting may be defined by the following Expression 10.

$$Etwisting = d / ( dbase ) \qquad Expression 10$$

It is preferable that the degree of twisting Etwisting defined by Expression 10 be 1.01 to 1.1 or less.

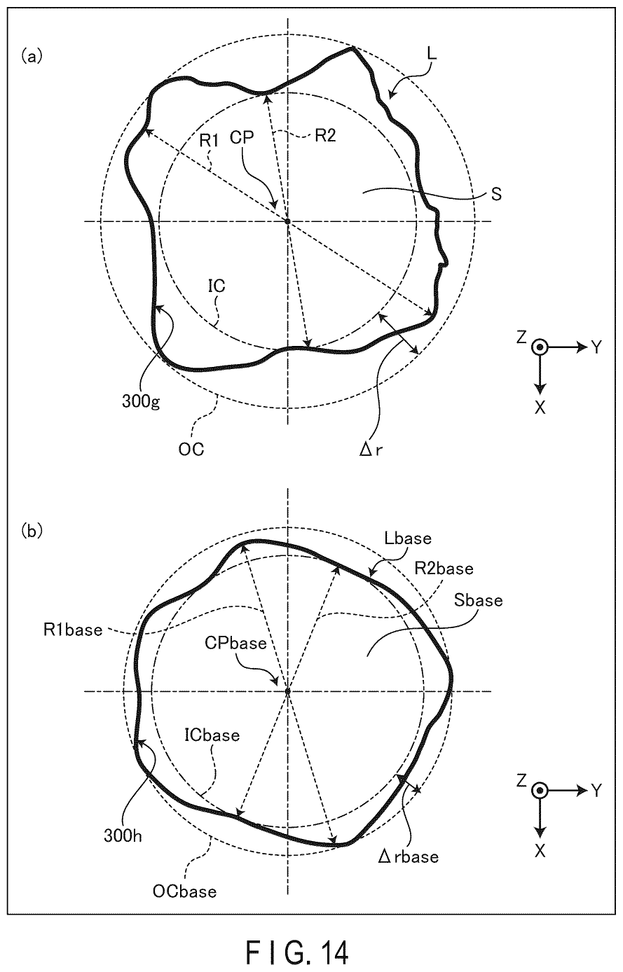

FIG. 14 exemplifies a parameter relating to the degree of distortion of a planar shape. The parameter relating to the degree of distortion of a planar shape includes the degree to which a hole pattern is distorted with respect to a reference planar shape. The degree of distortion of a planar shape includes, for example, parameters depending on roundness, circularity, ellipticity, and the like.

A reference planar shape of a hole pattern may be a perfect circle. A roundness index indicates the closeness to a perfect circle. For example, as illustrated in the part (a) of FIG. 14, it is possible to define the roundness index as a radius difference Δr between an inscribed circle IC and a circumscribed circle OC in and about the shape of a side surface 300g of the hole pattern 300 to be evaluated in the XY plane at the middle position in the Z direction. The roundness index Δr comes closer to 0 as the planar shape comes closer to a perfect circle. A degree of distortion Eplanar of the planar shape may correspond to the roundness index and may be defined by the following Expression 11.

$$Eplanar = Δ r \qquad Expression 11$$

It is preferable that the degree of distortion Eplanar defined by Expression 11 be 5 nm or less. It is more preferable that the degree of distortion Eplanar be 2.5 nm or less. It is still more preferable that the degree of distortion Eplanar be 0 nm.

Alternatively, when Δrbase represents the radius difference between an inscribed circle ICbase and a circumscribed circle OCbase in and about the shape of a side surface 300h of the hole pattern 300 obtained in a case in which dry etching is conducted under the base condition in the XY plane at the middle position in the Z direction as illustrated in the part (b) of FIG. 14, the degree of distortion Eplanar of the planar shape may be defined by the following Expression 12.

$$Eplanar = ( Δ r ) / ( Δ rbase ) \qquad Expression 12$$

It is preferable that the degree of distortion Eplanar defined by Expression 12 be 5 nm or less. It is more preferable that the degree of distortion Eplanar be 2.5 nm or less. It is still more preferable that the degree of distortion Eplanar be 0 nm.

A reference planar shape of a hole pattern may be a circle. The circularity indicates the closeness to a circle. It is possible to define the circularity as 4π-area/perimeter squared. The circularity comes closer to 1 as the planar shape comes closer to a circle. The degree of distortion Eplanar of the planar shape may be circularity. For example, as illustrated in the part (a) of FIG. 14, when S represents the area of the shape of the side surface 300g of the hole pattern 300 to be evaluated in the XY plane at the middle position in the Z direction and L represents the perimeter of the shape in the XY plane, the degree of distortion Eplanar may be defined by the following Expression 13.

$$Eplanar = 4 π \times S / {L}^{2} \qquad Expression 13$$

It is preferable that the degree of distortion Eplanar defined by Expression 13 be 1.1 or less. It is more preferable that the degree of distortion Eplanar be 1.05 or less. It is still more preferable that the degree of distortion Eplanar be 1.

Alternatively, when Sbase represents the area of the shape of the side surface 300h of the hole pattern 300 obtained in a case in which dry etching is conducted under the base condition in the XY plane at the middle position in the Z direction and Lbase represents the perimeter of the shape in the XY plane as illustrated in the part (b) of FIG. 14, the degree of distortion Eplanar of the planar shape may be defined by the following Expression 14.

$$Eplanar = ( 4 π \times S / {L}^{2} ) / ( 4 π \times Sbase / {Lbase}^{2} ) = ( S \times {Lbase}^{2} ) / ( Sbase \times {L}^{2} ) \qquad Expression 14$$

It is preferable that the degree of distortion Eplanar defined by Expression 14 be 1.1 or less. It is more preferable that the degree of distortion Eplanar be 1.05 or less. It is still more preferable that the degree of distortion Eplanar be 1.

A reference planar shape of a hole pattern may be a circle. The ellipticity indicates how much a circular shape is distorted into an elliptical shape. It is possible to define the ellipticity as “1−shorter diameter/diameter”. The ellipticity comes closer to 0 as the planar shape comes closer to a perfect circle. The degree of distortion Eplanar of the planar shape may be ellipticity. For example, when R1 and R2 respectively represent a longer diameter and a shorter diameter orthogonal to each other in the shape in the XY plane passing a center CP of the side surface 300g of the hole pattern 300 to be evaluated, the degree of distortion Eplanar may be defined by the following Expression 15.

$$Eplanar = 1 - R 2 / R 1 \qquad Expression 15$$

It is preferable that the degree of distortion Eplanar defined by Expression 15 be 1.1 or less. It is more preferable that the degree of distortion Eplanar be 1.05 or less. It is still more preferable that the degree of distortion Eplanar be 1.

Alternatively, when R1base represents the maximum diameter of the shape in the XY plane passing a center CPbase of the side surface 300h of the hole pattern 300 obtained in a case in which dry etching is conducted under a base condition and R2base represents the minimum diameter as illustrated in the part (b) of FIG. 14, the degree of distortion Eplanar may be defined by the following Expression 16.

$$Eplanar = ( R 1 / B ) / ( R 1 base / R 2 base ) = ( R 1 \times R 2 base ) / ( R 2 \times R 1 base ) \qquad Expression 16$$

It is preferable that the degree of distortion Eplanar defined by Expression 16 be 1.1 or less. It is more preferable that the degree of distortion Eplanar be 1.05 or less. It is still more preferable that the degree of distortion Eplanar be 1.

It is improved more than, for example, under the reference processing conditions that the expressions of the respective parameters as illustrated above in FIGS. 12 to 14 as the third modification example of the embodiment come closer to the preferable values or fall within the preferable value ranges. In addition, it is deteriorated more than, for example, under the reference processing conditions that the expressions of the respective parameters as illustrated in FIGS. 12 to 14 go farther from the preferable values or fall out of the preferable value ranges.

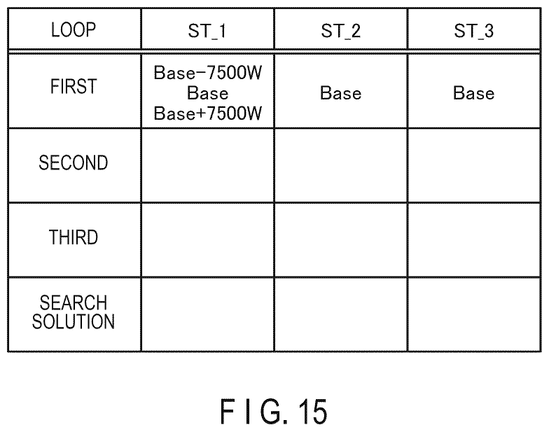

Alternatively, a processing condition may be optimized (S3) as illustrated in FIGS. 15 to 20 as a fourth modification example of the embodiment. Each of FIGS. 15 to 20 is a diagram illustrating a use case for optimizing a processing condition in the fourth modification example of the embodiment.

To optimize a processing condition (S3), a loop of S4 to S9 is repeated.

In the first loop, as illustrated in FIG. 15, a condition is assigned for step ST_1 and base conditions are adopted for steps ST_2 and ST_3. That is, step ST_1 is selected as a step of interest (S4) and a candidate processing condition “Base −7500 W” and a candidate processing condition “Base+7500 W” are generated as processing conditions for step ST_1 in addition to a base condition “Base” (S5). At this time, the processing conditions for steps ST_2 and ST_3 are the base conditions “Base”.

The “degree of bowing” and the “degree of twisting” are predicted under each of the base condition “Base”, the candidate processing condition “Base −7500 W”, and the candidate processing condition “Base+7500 W” for step ST_1 (S6). The “degree of bowing” and the “degree of twisting” obtained in a case in which any of the processing conditions for steps ST_1, ST_2, and ST_3 is the base condition “Base” are each predicted. The “degree of bowing” and the “degree of twisting” obtained in a case in which the processing conditions for steps ST_1, ST_2, and ST_3 are the candidate processing condition “Base −7500 W”, the base condition “Base”, and the base condition “Base”, respectively, are each predicted. The “degree of bowing” and the “degree of twisting” obtained in a case in which the processing conditions for steps ST_1, ST_2, and ST_3 are the candidate processing condition “Base+7500 W”, the base condition “Base”, and the base condition “Base”, respectively, are each predicted.

Depending on the “degree of bowing” and the “degree of twisting”, a candidate processing condition under which at least one of the “degree of bowing” and the “degree of twisting” deteriorates more than under the reference processing condition among the candidate processing condition “Base −7500 W” and the candidate processing condition “Base+7500 W” for step ST_1 is excluded (S7).

A candidate processing condition under which at least one of the “degree of bowing” and the “degree of twisting” is improved more than under the reference processing condition and the other deteriorates more than under the reference processing condition may be excluded as a candidate processing condition under which the two parameters are traded off relating to a processed shape.

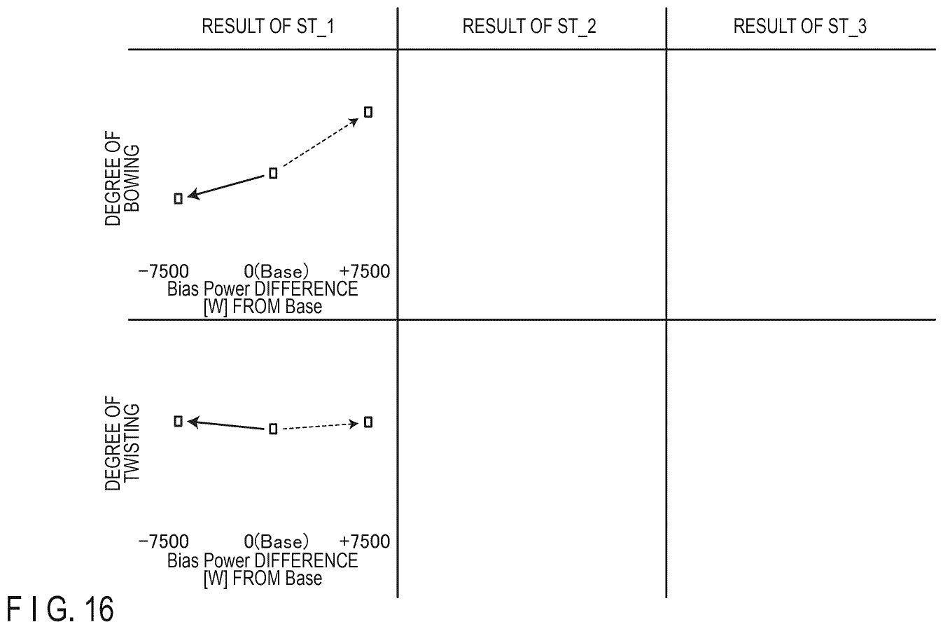

As illustrated in FIG. 16, the “degree of bowing” is improved and the “degree of twisting” substantially maintains the status quo without deteriorating under the candidate processing condition “Base −7500 W”. The candidate processing condition “Base −7500 W” is not regarded as a candidate processing condition that does not satisfy the predetermined processing condition or is not excluded. FIG. 16 illustrates, by a solid arrow, that the candidate processing condition “Base −7500 W” is not excluded.

As illustrated in FIG. 16, the “degree of bowing” deteriorates and the “degree of twisting” substantially maintains the status quo without deteriorating under the candidate processing condition “Base+7500 W”. The candidate processing condition “Base+7500 W” is excluded as a candidate processing condition under which one parameter has a deteriorating direction relating to a processed shape. FIG. 16 illustrates, by a dotted arrow, that the candidate processing condition “Base+7500 W” is excluded.

The processing condition “Base −7500 W” under which more improvements are made among the processing conditions “Base” and “Base −7500 W” left after the exclusion of the base condition “Base”, the candidate processing condition “Base −7500 W”, and the candidate processing condition “Base+7500 W” for step ST_1 is selected as the first solution (S8).

If the “degree of bowing” and the “degree of twisting” in each of the steps do not converge in the permissible ranges (No in S9), the second loop is carried out.

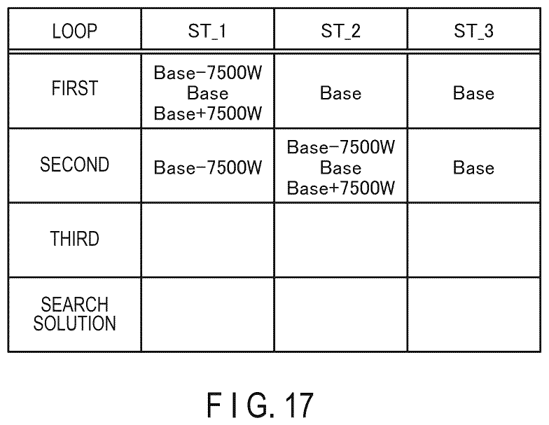

In the second loop, as illustrated in FIG. 17, a condition is assigned for step ST_2 and base conditions are adopted for steps ST_1 and ST_3. That is, step ST_2 is selected as a step of interest (S4) and a candidate processing condition “Base −7500 W” and a candidate processing condition “Base+7500 W” are generated as processing conditions for step ST_2 in addition to the base condition “Base” (S5). At this time, the processing conditions for steps ST_1 and ST_3 are the first solution “Base −7500 W” and the base condition “Base”.

The “degree of bowing” and the “degree of twisting” are predicted under each of the base condition “Base”, the candidate processing condition “Base −7500 W”, and the candidate processing condition “Base+7500 W” for step ST_2 (S6). The “degree of bowing” and the “degree of twisting” obtained in a case in which the processing conditions for steps ST_1, ST_2, and ST_3 are the first solution “Base −7500 W”, the base condition “Base”, and the base condition “Base”, respectively, are each predicted. The “degree of bowing” and the “degree of twisting” obtained in a case in which the processing conditions for steps ST_1, ST_2, and ST_3 are the first solution “Base −7500 W”, the candidate processing condition “Base −7500 W”, and the base condition “Base”, respectively, are each predicted. The “degree of bowing” and the “degree of twisting” obtained in a case in which the processing conditions for steps ST_1, ST_2, and ST_3 are the first solution “Base −7500 W”, the candidate processing condition “Base+7500 W”, and the base condition “Base”, respectively, are each predicted.

Depending on the “degree of bowing” and the “degree of twisting”, a candidate processing condition under which at least one of the “degree of bowing” and the “degree of twisting” deteriorates more than under the reference processing condition among the candidate processing condition “Base −7500 W” and the candidate processing condition “Base+7500 W” for step ST_2 is excluded (S7).

A candidate processing condition under which at least one of the “degree of bowing” and the “degree of twisting” is improved more than under the reference processing condition and the other deteriorates more than under the reference processing condition may be excluded as a candidate processing condition under which the two parameters are traded off relating to a processed shape.

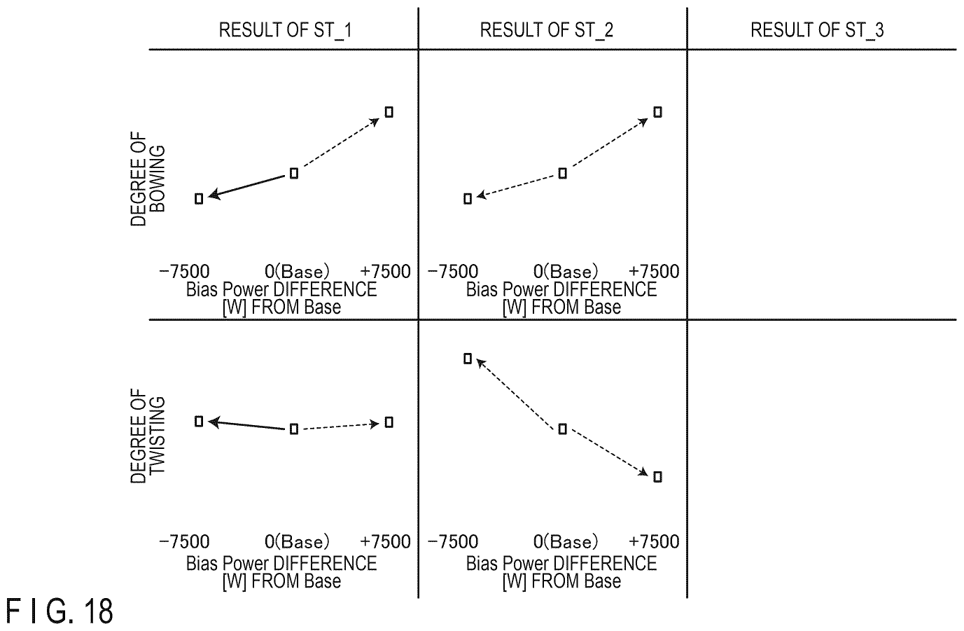

As illustrated in FIG. 18, the candidate processing condition “Base −7500 W” is excluded as a candidate processing condition under which the “degree of bowing” is improved, the “degree of twisting” deteriorates, and the two parameters are traded off relating to a processed shape. FIG. 18 illustrates, by a dotted arrow, that the candidate processing condition “Base −7500 W” is excluded.

As illustrated in FIG. 18, the candidate processing condition “Base+7500 W” is excluded as a candidate processing condition under which the “degree of bowing” deteriorates, the “degree of twisting” is improved, and the two parameters are traded off relating to a processed shape. FIG. 18 illustrates, by a dotted arrow, that the candidate processing condition “Base+7500 W” is excluded.

As illustrated in FIG. 18, the processing condition “Base” left after the exclusion of the base condition “Base”, the candidate processing condition “Base −7500 W”, and the candidate processing condition “Base+7500 W” for step ST_1 is selected as the second solution (S8).

If the “degree of bowing” and the “degree of twisting” in each of the steps do not converge in the permissible ranges (No in S9), the third loop is carried out.

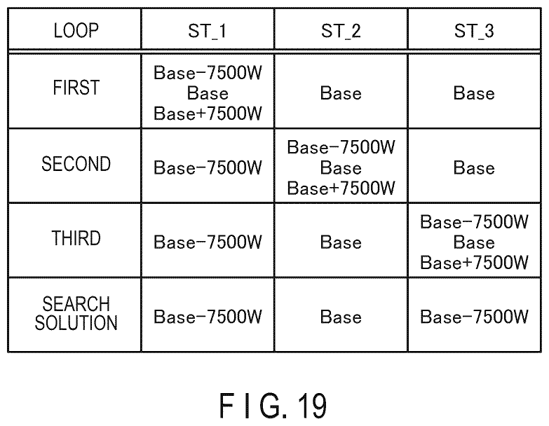

In the third loop, as illustrated in FIG. 19, a condition is assigned for step ST_3 and the first solution “Base −7500 W” and the second solution “Base” are adopted for steps ST_1 and ST_2. That is, step ST_3 is selected as a step of interest (S4) and a candidate processing condition “Base −7500 W” and a candidate processing condition “Base+7500 W” are generated as processing conditions for step ST_3 in addition to the base condition “Base” (S5). At this time, the processing conditions for steps ST_1 and ST_2 are the first solution “Base −7500 W” and the second solution “Base”.

The “degree of bowing” and the “degree of twisting” are predicted under each of the base condition “Base”, the candidate processing condition “Base −7500 W”, and the candidate processing condition “Base+7500 W” for step ST_3 (S6). The “degree of bowing” and the “degree of twisting” obtained in a case in which the processing conditions for steps ST_1, ST_2, and ST_3 are the first solution “Base −7500 W”, the second solution “Base”, and the base condition “Base”, respectively, are each predicted. The “degree of bowing” and the “degree of twisting” obtained in a case in which the processing conditions for steps ST_1, ST_2, and ST_3 are the first solution “Base −7500 W”, the second solution “Base”, and the candidate processing condition “Base −7500 W”, respectively, are each predicted. The “degree of bowing” and the “degree of twisting” obtained in a case in which the processing conditions for steps ST_1, ST_2, and ST_3 are the first solution “Base −7500 W”, the second solution “Base”, and the candidate processing condition “Base+7500 W”, respectively, are each predicted.

Depending on the “degree of bowing” and the “degree of twisting”, a candidate processing condition under which at least one of the “degree of bowing” and the “degree of twisting” deteriorates more than under the reference processing condition among the candidate processing condition “Base −7500 W” and the candidate processing condition “Base+7500 W” for step ST_2 is excluded (S7).

A candidate processing condition under which at least one of the “degree of bowing” and the “degree of twisting” is improved more than under the reference processing condition and the other deteriorates more than under the reference processing condition may be excluded as a candidate processing condition under which the two parameters are traded off relating to a processed shape.

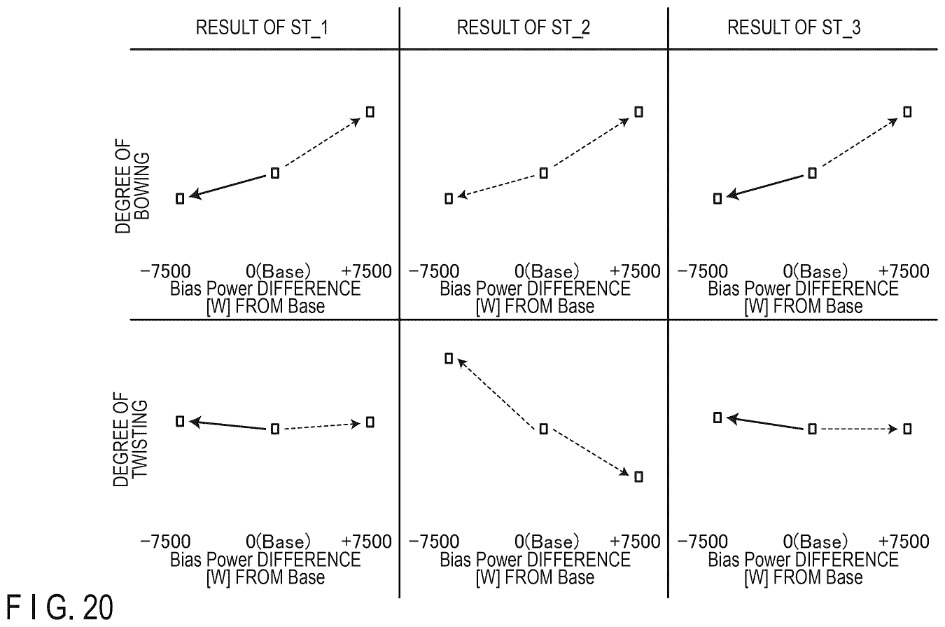

As illustrated in FIG. 20, the “degree of bowing” is improved and the “degree of twisting” substantially maintains the status quo without deteriorating under the candidate processing condition “Base −7500 W”. The candidate processing condition “Base −7500 W” is not regarded as a candidate processing condition that does not satisfy the predetermined condition or is not excluded. FIG. 20 illustrates, by a solid arrow, that the candidate processing condition “Base −7500 W” is not excluded.

As illustrated in FIG. 20, the “degree of bowing” deteriorates and the “degree of twisting” substantially maintains the status quo without deteriorating under the candidate processing condition “Base+7500 W”. The candidate processing condition “Base+7500 W” is excluded as a candidate processing condition under which one parameter has a deteriorating direction relating to a processed shape. FIG. 20 illustrates, by a dotted arrow, that the candidate processing condition “Base+7500 W” is excluded.

As illustrated in FIG. 20, “Base −7500 W” under which more improvements are made among the processing conditions “Base” and “Base −7500 W” left after the exclusion of the base condition “Base”, the candidate processing condition “Base −7500 W”, and the candidate processing condition “Base+7500 W” for step ST_3 is selected as the third solution (S8).

If the “degree of bowing” and the “degree of twisting” in each of the steps converge in the permissible ranges (Yes in S9), the processing conditions for steps ST_1, ST_2, and ST_3 of the multiple steps are used as search solutions at the first solution “Base −7500 W”, the second solution “Base”, and the third solution “Base −7500 W”, respectively, and the condition setting processing (S1) is completed.

In this way, in the condition setting method, the optimization is repeated while the step of interest among the multiple steps is sequentially shifted from the first step to the last step. This makes it possible to optimize the processing conditions for the respective multiple steps while taking into consideration the chronological influence of the respective steps and efficiently set the processing conditions for the respective steps.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A condition setting method comprising
sequentially shifting a step of interest among multiple steps of substrate processing from a first step to a last step; and
at each step of interest, determining a processing condition for optimizing a processed shape during the step of interest, and using the determined processing condition as a beginning processing condition in another step of the multiple steps.

2. The condition setting method of claim 1, wherein the step of determining includes:
predicting a plurality of parameters relating to the processed shape in the step of interest under each of a reference processing condition and one or more candidate processing conditions,
excluding a candidate processing condition that does not satisfy a predetermined condition among the one or more candidate processing conditions depending on the plurality of predicted parameters, and
determining, as a processing condition for the step of interest, one of one or more processing conditions left after exclusion of the reference processing condition and the one or more candidate processing conditions.

3. The condition setting method of claim 2, wherein
the step of predicting includes predicting a first parameter and a second parameter relating to the processed shape in the step of interest under each of the reference processing condition and the one or more candidate processing conditions, and
the step of excluding includes excluding a candidate processing condition under which at least one of the first parameter and the second parameter deteriorates more than under the reference processing condition among the one or more candidate processing conditions.

4. The condition setting method of claim 3, wherein
the step of predicting includes predicting the first parameter and the second parameter relating to the processed shape in the step of interest under each of the reference processing condition and the one or more candidate processing conditions, and
the step of excluding includes excluding, as the candidate processing condition that does not satisfy the predetermined condition, a candidate processing condition under which at least one of the first parameter and the second parameter is improved more than under the reference processing condition and another of the first parameter and the second parameter deteriorates more than under the reference processing condition among the one or more candidate processing conditions.

5. The condition setting method of claim 2, wherein
the step of predicting includes predicting a first parameter and a second parameter relating to the processed shape in the step of interest under each of the reference processing condition and the one or more candidate processing conditions, and
the step of excluding includes excluding a candidate processing condition under which an amount by which at least one of the first parameter and the second parameter deteriorates more than under the reference processing condition exceeds a threshold among the one or more candidate processing conditions.

6. The condition setting method of claim 2, wherein
the step of predicting includes predicting the first parameter and the second parameter relating to the processed shape in the step of interest under each of the reference processing condition and the one or more candidate processing conditions, and
the step of excluding includes excluding, as the candidate processing condition that does not satisfy the predetermined condition, a candidate processing condition under which at least one of the first parameter and the second parameter falls out of a permissible range and deteriorates more than under the reference processing condition among the one or more candidate processing conditions.

7. The condition setting method of claim 2, wherein the step of predicting includes predicting the processed shape in the step of interest among the multiple steps under each of the reference processing condition and the one or more candidate processing conditions by using a learned model subjected to machine learning.

8. The condition setting method of claim 1, wherein the substrate processing includes dry etching.

9. The condition setting method of claim 1, wherein multiple cycles of the step of sequentially shifting and the step of determining the processing condition for optimizing the processed shape at each step of interest are carried out.

10. A method for manufacturing a semiconductor device, the method comprising:
determining processing conditions for each of the multiple steps of substrate processing according to the condition setting method of claim 1; and
performing the substrate processing having the multiple steps under the processing conditions determined for each of the steps.

11. A condition setting device comprising:
a storage unit configured to store a temporary processing condition for each of steps of substrate processing having multiple steps; and
a control unit configured to:
sequentially shift a step of interest among the multiple steps of substrate processing from a first step to a last step; and
at each step of interest, determining a processing condition for optimizing a processed shape during the step of interest, and using the determined processing condition as a beginning processing condition in another step of the multiple steps.

12. The condition setting device according to claim 11, wherein
the multiple steps include a first step, a second step, and a third step, and a second step
when the step of interest is the first step, the temporary processing condition for the second step stored in the storage unit and the temporary processing condition for the third step stored in the storage unit are used while determining the processing condition for optimizing the processed shape during the first step.

13. The condition setting device according to claim 12, wherein
when the step of interest is the second step, the determined processing condition for the first step and the temporary processing condition for the third step stored in the storage unit are used while determining the processing condition for optimizing the processed shape during the second step.

14. The condition setting device according to claim 13, wherein
when the step of interest is the third step, the determined processing condition for the first step and the determined processing condition for the second step are used while determining the processing condition for optimizing the processed shape during the third step.

15. A substrate processing apparatus comprising:
a substrate processing unit configured to process a substrate;
the condition setting device of claim 11 configured to set processing conditions for the multiple steps; and
a controller configured to control the substrate processing unit and perform the substrate processing having the multiple steps under the processing conditions determined for each of the multiple steps.

16. The substrate processing apparatus according to claim 15, wherein the substrate processing unit includes:
a treatment container for housing a substrate to be processed;
a gas flow rate adjusting section;
a pressure adjusting section; and
a temperature adjusting section, wherein
for each of the multiple steps, the controller controls one or more of the gas flow rate adjusting section, the pressure adjusting section, and the temperature adjusting section to realize the processing conditions determined for said each of the multiple steps.

17. The substrate processing apparatus according to claim 16, wherein the substrate processing unit is configured to perform dry etching on the substrate housed in the treatment container.

18. The substrate processing apparatus according to claim 17, wherein
the multiple steps of the dry etching include a first step, a second step, and a third step, and a second step
when the step of interest is the first step, the temporary processing condition for the second step stored in the storage unit and the temporary processing condition for the third step stored in the storage unit are used while determining the processing condition for optimizing the processed shape during the first step.

19. The substrate processing apparatus according to claim 18, wherein
when the step of interest is the second step, the determined processing condition for the first step and the temporary processing condition for the third step stored in the storage unit are used while determining the processing condition for optimizing the processed shape during the second step.

20. The substrate processing apparatus according to claim 19, wherein
when the step of interest is the third step, the determined processing condition for the first step and the determined processing condition for the second step are used while determining the processing condition for optimizing the processed shape during the third step.
